(19) United States
(12) Patent Application Publication
(10) Pub. No.: US 2025/0359158 A1
(43) Pub. Date: Nov. 20, 2025

(54) SEMICONDUCTOR DEVICE INCLUDING A SPECIALIZED GATE ELECTRODE STRUCTURE

(71) Applicant: SAMSUNG ELECTRONICS CO., LTD., SUWON-SI (KR)

(72) Inventors: YOUNGJIN YANG, Suwon-si (KR); HYOJIN KIM, Suwon-si (KR); KYOUNG-MI PARK, Suwon-si (KR); DONGHOON HWANG, Suwon-si (KR)

(21) Appl. No.: 18/972,476

(22) Filed: Dec. 6, 2024

(30) Foreign Application Priority Data
May 16, 2024 (KR) 10-2024-0064011

(51) Int. Cl. H01L 29/423; H01L 21/28; H01L 29/06; H01L 29/08; H01L 29/66; H01L 29/775; H01L 29/786

(52) U.S. Cl. CPC H10D 30/6735; H01L 21/28123; H10D 30/014; H10D 30/43; H10D 30/6757; H10D 62/121; H10D 62/151; H10D 64/017

(57) ABSTRACT

A semiconductor device includes a first source/drain structure and a second source/drain structure spaced apart from each other. A first channel structure is connected to the first source/drain structure. A second channel structure is connected to the second source/drain structure. A separation insulating layer is disposed between the first and second source/drain structures and between the first and second channel structures. A gate electrode overlaps the separation insulating layer, the first channel structure, and the second channel structure. The gate electrode includes a first channel overlap portion overlapping the first channel structure, a second channel overlap portion overlapping the second channel structure, and a bridge portion disposed between the first channel overlap portion and the second channel overlap portion.

### CROSS-REFERENCE TO RELATED APPLICATIONS

This U.S. non-provisional patent application claims priority under 35 U.S.C. § 119 to Korean Patent Application No. 10-2024-0064011, filed on May 16, 2024, in the Korean Intellectual Property Office, the entire contents of which are hereby incorporated by reference.

### TECHNICAL FIELD

The present disclosure relates to a semiconductor device, and in particular, to a semiconductor device including a specialized gate electrode structure.

### DISCUSSION OF THE RELATED ART

Semiconductor devices generally include an integrated circuit composed of metal-oxide-semiconductor field-effect transistors (MOS-FETs). To meet an increasing demand for semiconductor devices with a small pattern size and a reduced design rule, the MOS-FETs are being scaled down. The scale-down of the MOS-FETs may lead to deterioration in operation characteristics of the semiconductor device. Accordingly, a variety of studies are being conducted to overcome technical limitations associated with the scale-down of semiconductor devices and to provide high performance semiconductor device.

### SUMMARY

A semiconductor device includes a first source/drain structure and a second source/drain structure spaced apart from each other. A first channel structure is connected to the first source/drain structure, a second channel structure is connected to the second source/drain structure, a separation insulating layer is disposed between the first and second source/drain structures and between the first and second channel structures. A gate electrode overlaps the separation insulating layer, the first channel structure, and the second channel structure. The gate electrode includes a first channel overlap portion overlapping the first channel structure, a second channel overlap portion overlapping the second channel structure, and a bridge portion disposed between the first channel overlap portion and the second channel overlap portion. A level of a top surface of the bridge portion is higher than a level of a top surface of the first channel overlap portion and a level of a top surface of the second channel overlap portion.

A semiconductor device includes a first source/drain structure and a second source/drain structure spaced apart from each other. A first channel structure is connected to the first source/drain structure. A second channel structure is connected to the second source/drain structure. A separation insulating layer is disposed between the first and second source/drain structures and between the first and second channel structures. A gate electrode overlaps the separation insulating layer, the first channel structure, and the second channel structure. The gate electrode includes a first channel overlap portion overlapping the first channel structure, a second channel overlap portion overlapping the second channel structure, and a bridge portion connecting the first channel overlap portion to the second channel overlap portion. The bridge portion includes a first portion connected to the first channel overlap portion, a second portion connected to the second channel overlap portion, and a third portion disposed between the first portion and the second portion. The third portion of the bridge portion is disposed at a level that is higher than the separation insulating layer, and the third portion of the bridge portion overlaps the separation insulating layer.

A semiconductor device includes a first source/drain structure and a second source/drain structure spaced apart from each other. A first channel structure is connected to the first source/drain structure. A second channel structure is connected to the second source/drain structure. A first active contact is disposed on the first source/drain structure. A second active contact is disposed on the second source/drain structure. A separation insulating layer is disposed between the first and second source/drain structures, between the first and second channel structures, and between the first and second active contacts. A gate electrode overlaps the separation insulating layer, the first channel structure, and the second channel structure. A gate insulating layer is disposed between the gate electrode and the separation insulating layer. A capping insulating layer is disposed on the first active contact. The second active contact, and the gate electrode, and a gate connection pattern are disposed on the gate electrode. A bridge insulating layer is in contact with the gate electrode, the gate connection pattern, and the capping insulating layer. A contact connection pattern is disposed on the first active contact. The gate electrode includes a bridge portion in contact with the bridge insulating layer and the gate connection pattern. A width of the bridge portion increases as a level may be lowered.

A method of fabricating a semiconductor device includes forming a semiconductor layer and a sacrificial semiconductor layer. A separation insulating layer is formed to penetrate the semiconductor layer and the sacrificial semiconductor layer. The semiconductor layer and the sacrificial semiconductor layer are etched. A semiconductor pattern is formed by the etching of the semiconductor layer. A first source/drain structure and second source/drain structure are spaced apart from each other with the separation insulating layer interposed therebetween. The sacrificial semiconductor layer is removed. A gate electrode is formed to overlap the semiconductor pattern.

A bridge sacrificial pattern is formed on the gate electrode. The bridge sacrificial pattern is etched to form a gate sacrificial pattern. The gate sacrificial pattern is removed to form a first space. A gate connection pattern is formed in the first space.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1A is a plan view illustrating a semiconductor device according to an embodiment of the inventive concept.

FIG. 1B is a cross-sectional view taken along a line A-A′ of FIG. 1A.

FIG. 1C is a cross-sectional view taken along a line B-B′ of FIG. 1A.

FIG. 1D is a cross-sectional view taken along a line C-C′ of FIG. 1A.

FIG. 1E is an enlarged cross-sectional view illustrating a portion ‘E1’ of FIG. 1B.

FIG. 1F is an enlarged cross-sectional view illustrating a portion ‘E2’ of FIG. 1C.

FIGS. 2A, 2B, 2C, 3A, 3B, 4A, 4B, 4C, 5A, 5B, 5C, 6A, 6B, 6C, 7A, 7B, 7C, 7D, 8A, 8B, 8C, 9A, 9B, 9C, 9D, 10A, 10B, 10C, 11A, 11B, and 11C are diagrams illustrating a method of fabricating a semiconductor device, according to an embodiment of the inventive concept. FIG. 12 is an enlarged cross-sectional view illustrating a semiconductor device according

to an embodiment of the inventive concept.

FIG. 13 is an enlarged cross-sectional view illustrating a semiconductor device according to an embodiment of the inventive concept.

FIG. 14 is an enlarged cross-sectional view illustrating a semiconductor device according to an embodiment of the inventive concept.

FIG. 15 is an enlarged cross-sectional view illustrating a semiconductor device according to an embodiment of the inventive concept.

### DETAILED DESCRIPTION

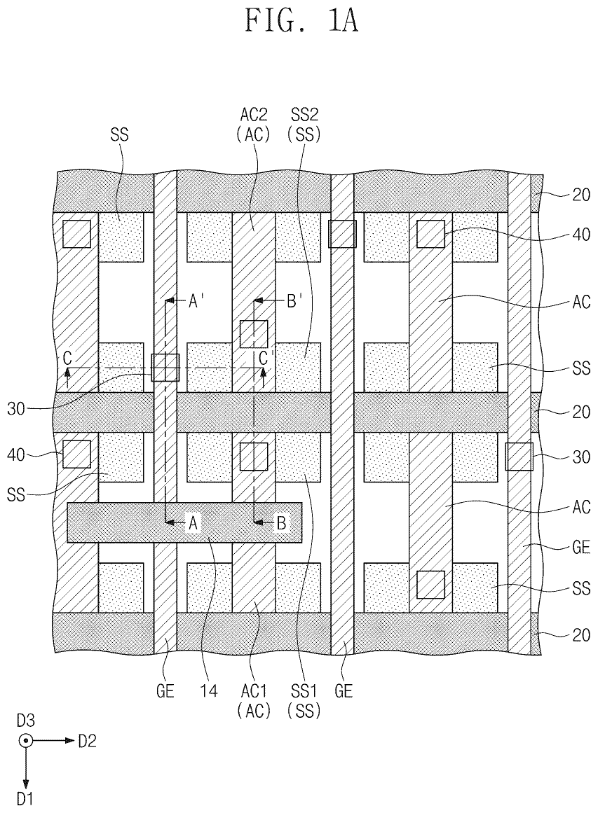

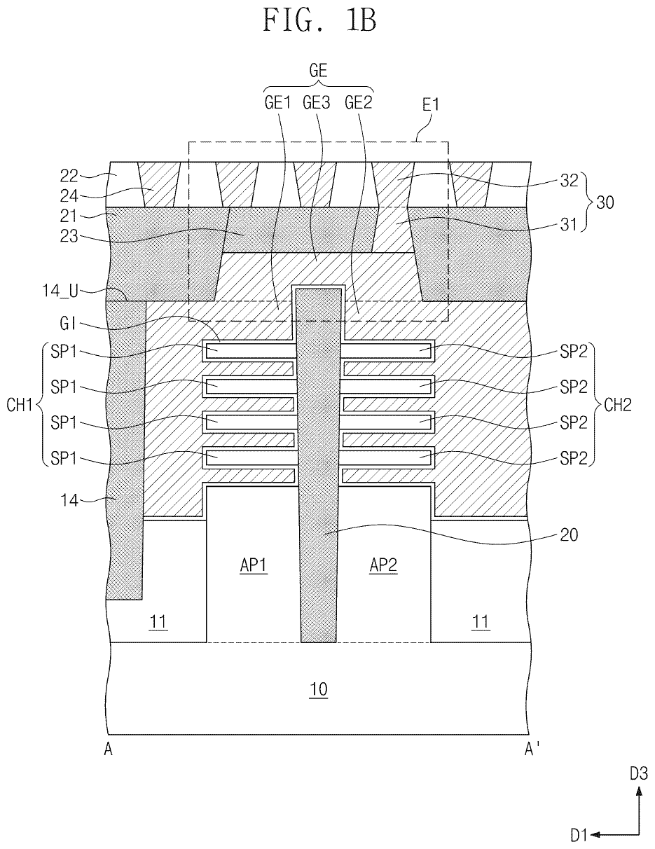

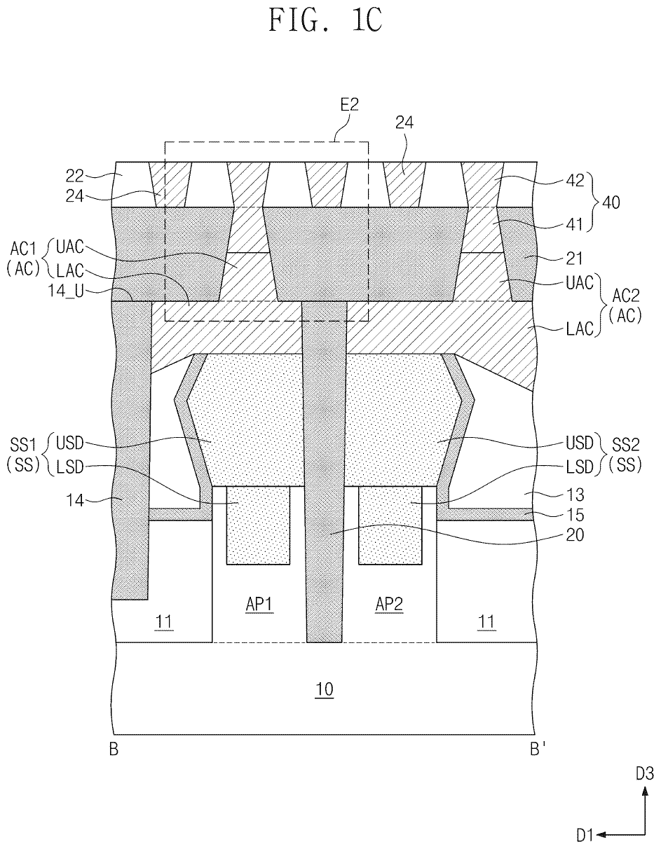

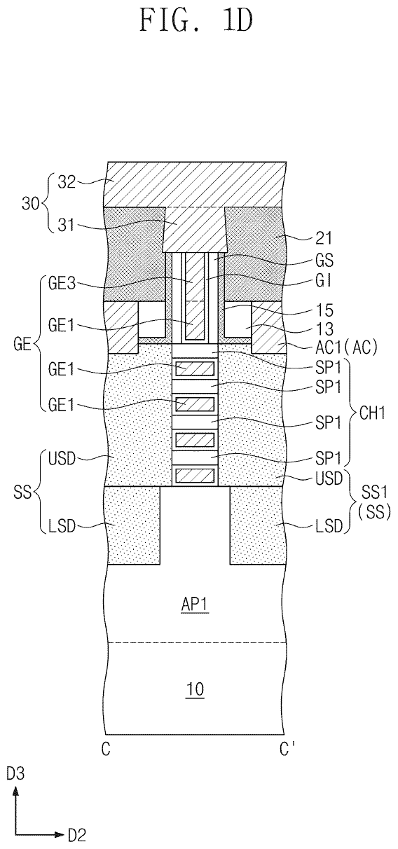

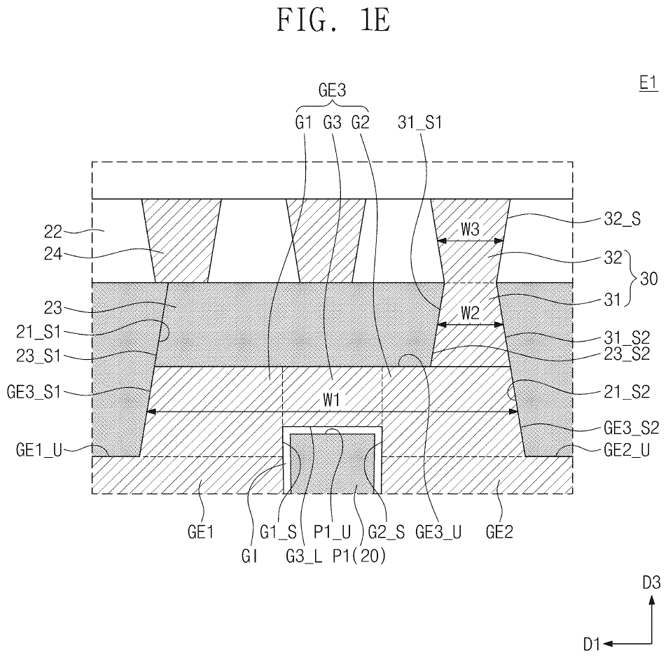

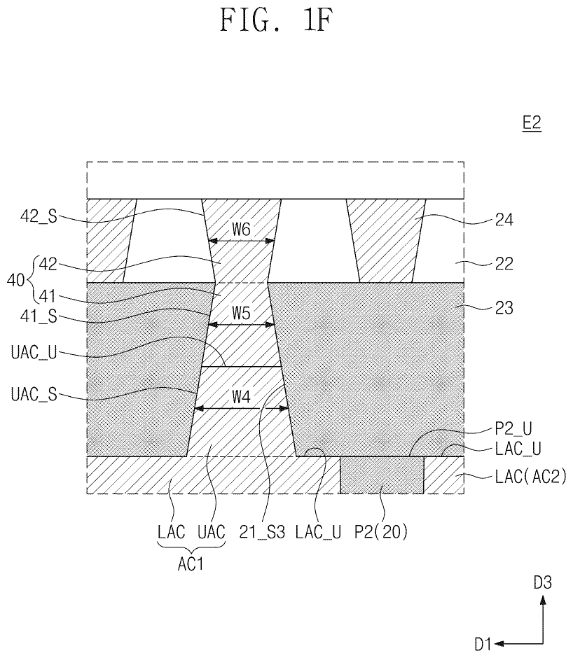

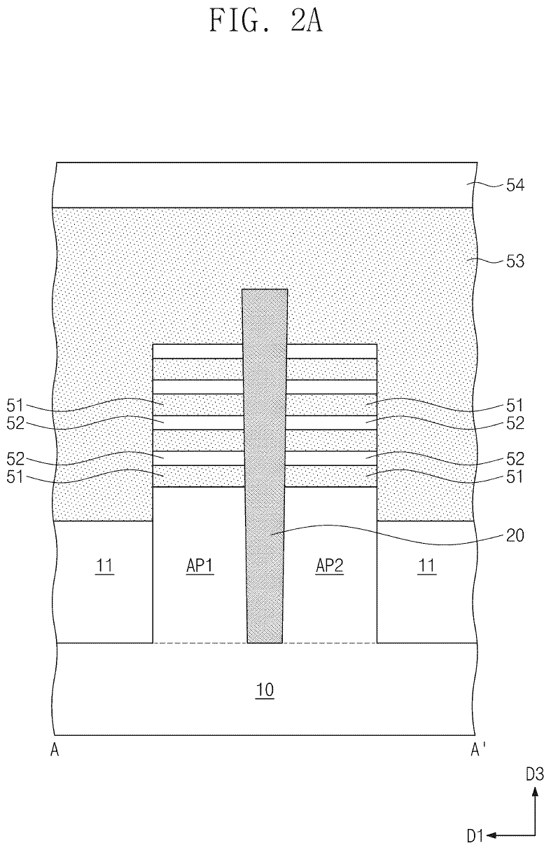

FIG. 1A is a plan view illustrating a semiconductor device according to an embodiment of the inventive concept. FIG. 1B is a cross-sectional view taken along a line A-A′ of FIG. 1A. FIG. 1C is a cross-sectional view taken along a line B-B′ of FIG. 1A. FIG. 1D is a cross-sectional view taken along a line C-C′ of FIG. 1A. FIG. 1E is an enlarged cross-sectional view illustrating a portion ‘E1’ of FIG. 1B. FIG. 1F is an enlarged cross-sectional view illustrating a portion ‘E2’ of FIG. 1C.

Referring to FIGS. 1A, 1B, 1C, and 1D, the semiconductor device may include a substrate 10. Logic transistors constituting a logic circuit may be disposed on the substrate 10. The substrate 10 may be a semiconductor substrate, an insulating substrate, a silicon-on-insulator (SOI) substrate, or a germanium-on-insulator (GOI) substrate. In an embodiment, the semiconductor substrate may be formed of or otherwise include silicon, germanium, silicon-germanium, GaP, or GaAs.

The substrate 10 may be a plate-shaped structure that extends in a first direction D1 and a second direction D2. The first and second directions D1 and D2 are different from one another. In an embodiment, the first and second directions D1 and D2 may be horizontal directions that are orthogonal to each other.

The substrate 10 may include active patterns AP1 and AP2. The active patterns AP1 and AP2 may extend in the second direction D2. The active patterns AP1 and AP2 may be spaced apart from each other in the first direction D1. The active patterns AP1 and AP2 may be upper portions of the substrate 10 protruding in a third direction D3. The third direction D3 might not be parallel to the first and second directions D1 and D2. In an embodiment, the third direction D3 may be a vertical direction that is orthogonal to the first and second directions D1 and D2.

The active patterns AP1 and AP2 may include a first active pattern AP1 and a second active pattern AP2. The first active pattern AP1 and the second active pattern AP2 may be two active patterns AP1 and AP2, which are adjacent to each other in the first direction D1. The first active pattern AP1 and the second active pattern AP2 may be spaced apart from each other in the first direction D1.

Device isolation layers 11 may be provided on the substrate 10. The first and second active patterns AP1 and AP2 may be disposed between the device isolation layers 11, which are spaced apart from each other in the first direction D1. The device isolation layers 11 may include an insulating material. In an embodiment, the device isolation layers 11 may be formed of or otherwise include an oxide material.

Channel structures CH1 and CH2 may overlap the active patterns AP1 and AP2 in the third direction D3. The channel structures CH1 and CH2 may include first channel structures CH1, which overlap the first active pattern AP1 in the third direction D3, and second channel structures CH2, which overlap the second active pattern AP2 in the third direction D3.

The channel structures CH1 and CH2, which overlap each active pattern AP1 or AP2 in the third direction D3, may be spaced apart from each other in the second direction D2. For example, the first channel structures CH1, which overlap the first active pattern AP1 in the third direction D3, may be spaced apart from each other in the second direction D2.

Each of the first channel structures CHI may include first semiconductor patterns SP1 arranged in the third direction D3. As used herein, the phrase, “arranged in a direction” means that the element or group has a largest dimension in the given direction. The first semiconductor patterns SP1 may be spaced apart from each other in the third direction D3. The first semiconductor patterns SP1 may overlap each other in the third direction D3. Each of the second channel structures CH2 may include second semiconductor patterns SP2 arranged in the third direction D3. The second semiconductor patterns SP2 may be spaced apart from each other in the third direction D3. The second semiconductor patterns SP2 may overlap each other in the third direction D3.

The number of the semiconductor patterns SP1 and SP2 in each channel structure CH1 or CH2 is not necessarily limited to that in the illustrated example. In an embodiment, the number of the semiconductor patterns SP1 and SP2 in each channel structure CH1 or CH2 may be less than or equal to 3 or may be greater than or equal to 5.

In an embodiment, the first and second semiconductor patterns SP1 and SP2 may be formed of or otherwise include silicon (Si). For example, the first and second semiconductor patterns SP1 and SP2 may be formed of or otherwise include crystalline silicon.

Source/drain structures SS may be provided on the active patterns AP1 and AP2. The source/drain structures SS, which are provided on each active pattern AP1 or AP2, may be spaced apart from each other in the second direction D2. The source/drain structures SS may include first source/drain structures SS1 on the first active pattern AP1 and second source/drain structures SS2 on the second active pattern AP2. The first source/drain structure SS1 may be connected to the first semiconductor patterns SP1 of the first channel structure CH1. The second source/drain structure SS2 may be connected to the second semiconductor patterns SP2 of the second channel structure CH2. Each of the source/drain structures SS may include a lower source/drain pattern LSD and an upper source/drain pattern USD.

The lower source/drain patterns LSD may be provided on the active pattern AP1 or AP2. The lower source/drain pattern LSD may be provided in the active pattern AP1 or AP2. The lower source/drain patterns LSD may be epitaxial patterns, which are formed by a selective epitaxial growth (SEG) process. In an embodiment, the lower source/drain patterns LSD may be formed of or otherwise include silicon (Si) or silicon-germanium (SiGe).

The upper source/drain patterns USD may be provided on the active pattern AP1 or AP2. The upper source/drain pattern USD may be provided on the lower source/drain pattern LSD. The upper source/drain pattern USD may be disposed between the channel structures CH1 and CH2, which are adjacent to each other in the second direction D2. The upper source/drain pattern USD may be connected to the semiconductor patterns SP1 and SP2 of the channel structure CH1 or CH2.

The upper source/drain patterns USD may be epitaxial patterns, which are formed by a selective epitaxial growth process. In an embodiment, the upper source/drain patterns USD may be formed of or otherwise include silicon (Si) or silicon-germanium (SiGe).

Separation insulating layers 20 may be provided. The separation insulating layers 20 may extend in the second direction D2. The separation insulating layers 20 may be spaced apart from each other in the first direction D1. One of the separation insulating layers 20 may be disposed between the first and second active patterns AP1 and AP2, between the first and second channel structures CH1 and CH2, and between the first and second source/drain structures SS1 and SS2. The first and second active patterns AP1 and AP2 may be spaced apart from each other in the first direction D1, with the separation insulating layer 20 interposed therebetween. The first and second channel structures CH1 and CH2 may be spaced apart from each other in the first direction D1, with the separation insulating layer 20 interposed therebetween. The first and second source/drain structures SS1 and SS2 may be spaced apart from each other in the first direction D1, with the separation insulating layer 20 interposed therebetween. The separation insulating layer 20 may include an insulating material. In an embodiment, the separation insulating layer 20 may include a nitride material.

Gate electrodes GE may be provided. The gate electrodes GE may extend in the first direction D1. One of the gate electrodes GE may overlap the first channel structure CH1, the second channel structure CH2, and the separation insulating layer 20 therebetween in the third direction D3. The gate electrode GE may be disposed between the upper source/drain patterns USD, which are adjacent to each other in the second direction D2.

The gate electrode GE and the semiconductor patterns SP1 and SP2 may constitute a three-dimensional field effect transistor (e.g., MBCFET or GAAFET). The gate electrode GE may include a conductive material. In an embodiment, the gate electrode GE may include a barrier layer and a conductive layer, which are formed of or otherwise include different materials from each other.

Gate insulating layers GI may be provided. The gate insulating layer GI may separate the gate electrode GE from the semiconductor patterns SP1 and SP2 of the channel structure CH1 or CH2. The gate insulating layer GI may be provided between the gate electrode GE and the semiconductor pattern SP1 or SP2 of the channel structure CH1 or CH2. The gate insulating layer GI may separate the gate electrode GE from the separation insulating layer 20. The gate insulating layer GI may be provided between the gate electrode GE and the separation insulating layer 20. The gate insulating layer GI may be in contact with the device isolation layer 11 and the separation insulating layer 20. The gate insulating layer GI may include an insulating material. In an embodiment, the gate insulating layer GI may include silicon oxide.

Gate spacers GS may be provided. The gate spacers GS may be disposed at both sides of the gate electrode GE. The gate spacers GS may include an insulating material.

A cover insulating layer 15 may be provided. The cover insulating layer 15 may be provided on the upper source/drain pattern USD, the separation insulating layer 20, and the gate spacer GS. The cover insulating layer 15 may include an insulating material. An insulating layer 13 may be provided on the cover insulating layer 15. The insulating layer 13 may include an insulating material.

A gate cutting insulating layer 14 may be provided. The gate cutting insulating layer 14 may be disposed between the gate electrodes GE, which are spaced apart from each other in the first direction D1. A side surface of the gate cutting insulating layer 14 may be in contact with the gate electrode GE, the device isolation layer 11, the cover insulating layer 15 and the insulating layer 13.

Active contacts AC may be provided on the upper source/drain patterns USD of the source/drain structures SS1 and SS2. The active contacts AC may include a first active contact AC1 on the first source/drain structure SS1 and a second active contact AC2 on the second source/drain structure SS2. The active contact AC may penetrate the cover insulating layer 15 and the insulating layer 13. The separation insulating layer 20 may be provided between the first and second active contacts AC1 and AC2. The first and second active contacts AC1 and AC2 may be spaced apart from each other in the first direction D1, with the separation insulating layer 20 interposed therebetween. The active contact AC may include a conductive material.

A capping insulating layer 21 may be provided on the active contacts AC and the gate electrodes GE. The capping insulating layer 21 may be in contact with the gate cutting insulating layer 14 and the separation insulating layer 20. The capping insulating layer 21 may include an insulating material.

An upper insulating layer 22 may be provided on the capping insulating layer 21. The upper insulating layer 22 may include an insulating material.

A bridge insulating layer 23 may be provided on the gate electrode GE. The bridge insulating layer 23 may be in contact with the gate electrode GE, the capping insulating layer 21, and the upper insulating layer 22. The bridge insulating layer 23 may be provided between the gate electrode GE and the upper insulating layer 22. The bridge insulating layer 23 may be enclosed by the capping insulating layer 21. The bridge insulating layer 23 may be disposed in the capping insulating layer 21.

The capping insulating layer 21 and the bridge insulating layer 23 may include a material having an etch selectivity with respect to the upper insulating layer 22. In an embodiment, the capping insulating layer 21 and the bridge insulating layer 23 may include a nitride material, and the upper insulating layer 22 may include an oxide material.

In an embodiment, the capping insulating layer 21 and the bridge insulating layer 23 may be formed of or otherwise include the same insulating material. In an embodiment, the capping insulating layer 21 and the bridge insulating layer 23 may be formed of or otherwise include different insulating materials from each other.

One of the gate electrodes GE may include a first channel overlap portion GE1, a second channel overlap portion GE2, and a bridge portion GE3. The first channel overlap portion GE1 may overlap the first channel structure CH1 in the third direction D3, and the second channel overlap portion GE2 may overlap the second channel structure CH2 in the third direction D3. The first channel overlap portion GE1 may include portions interposed between the first semiconductor patterns SP1 of the first channel structure CH1. The second channel overlap portion GE2 may include portions interposed between the second semiconductor patterns SP2 of the second channel structure CH2.

The bridge portion GE3 may be provided between the first and second channel overlap portions GE1 and GE2. The bridge portion GE3 may connect the first channel overlap portion GE1 to the second channel overlap portion GE2. The bridge portion GE3 may be disposed at a level that is higher than the first and second channel overlap portions GE1 and GE2. The bridge portion GE3 may be enclosed by the capping insulating layer 21. Each of the gate electrodes GE may include at least one bridge portion GE3.

The first and second channel overlap portions GE1 and GE2 may be spaced apart from each other in the first direction D1. The separation insulating layer 20 may be disposed between the first and second channel overlap portions GE1 and GE2. A side surface of the gate cutting insulating layer 14 may be in contact with a side surface of the first channel overlap portion GE1.

Each of the active contacts AC may include an upper portion UAC and a lower portion LAC. The upper portion UAC of the active contact AC may be disposed at a level that is higher than the lower portion LAC of the active contact AC. The upper portion UAC of the active contact AC may be enclosed by the capping insulating layer 21. The lower portion LAC of the active contact AC may be disposed between the separation insulating layers 20. The lower portion LAC of the active contact AC may be in contact with the upper source/drain pattern USD.

A gate connection pattern 30 may penetrate the upper insulating layer 22. The gate connection pattern 30 may be provided on the bridge portion GE3 of the gate electrode GE. The gate connection pattern 30 may be in contact with the capping insulating layer 21, the bridge insulating layer 23, the upper insulating layer 22, and the bridge portion GE3 of the gate electrode GE. The gate connection pattern 30 may include a conductive material.

The gate connection pattern 30 may include a lower portion 31 and an upper portion 32. The lower portion 31 of the gate connection pattern 30 may be disposed at a level that is lower than the upper portion 32 of the gate connection pattern 30. The lower portion 31 of the gate connection pattern 30 may be in contact with the bridge portion GE3 of the gate electrode GE, the capping insulating layer 21, and the bridge insulating layer 23. The upper portion 32 of the gate connection pattern 30 may be in contact with the upper insulating layer 22. A width of the lower portion 31 of the gate connection pattern 30 in the second direction D2 may be smaller than a width of the upper portion 32 of the gate connection pattern 30 in the second direction D2. The upper portion 32 of the gate connection pattern 30 may have a line-shaped pattern extending in the second direction D2. The lower portion 31 of the gate connection pattern 30 may have a contact-shaped pattern enclosed by the capping insulating layer 21.

A contact connection pattern 40 may penetrate the upper insulating layer 22. The contact connection pattern 40 may be provided on the upper portion UAC of the active contact AC. The contact connection pattern 40 may be in contact with the capping insulating layer 21, the upper insulating layer 22, and the upper portion UAC of the active contact AC. The contact connection pattern 40 may include a conductive material.

The contact connection pattern 40 may include a lower portion 41 and an upper portion 42. The lower portion 41 of the contact connection pattern 40 may be disposed at a level that is lower than the upper portion 42 of the contact connection pattern 40. The lower portion 41 of the contact connection pattern 40 may be in contact with the capping insulating layer 21 and the upper portion UAC of the active contact AC. The upper portion 42 of the contact connection pattern 40 may be in contact with the upper insulating layer 22. A width of the lower portion 41 of the contact connection pattern 40 in the second direction D2 may be smaller than a width of the upper portion 42 of the contact connection pattern 40 in the second direction D2. The upper portion 42 of the contact connection pattern 40 may have a line-shaped pattern extending in the second direction D2. The lower portion 41 of the contact connection pattern 40 may have a contact-shaped pattern enclosed by the capping insulating layer 21.

Conductive lines 24 may be provided in the upper insulating layer 22. The conductive line 24 may extend in the second direction D2. The upper portion 32 of the gate connection pattern 30 and the upper portion 42 of the contact connection pattern 40 may have a shape similar to the conductive line 24. The upper portion 32 of the gate connection pattern 30 and the upper portion 42 of the contact connection pattern 40 may be disposed at the same level as the conductive line 24. The conductive lines 24 may be spaced apart from each other in the first direction D1. The conductive line 24 may include a conductive material.

Referring to FIGS. 1E and 1F, the bridge portion GE3 may include a first side surface GE3_S1, which connects a top surface GE3_U of the bridge portion GE3 to a top surface GE1_U of the first channel overlap portion GE1, and a second side surface GE3_S2, which connects the top surface GE3_U of the bridge portion GE3 to a top surface GE2_U of the second channel overlap portion GE2. A distance between the first and second side surfaces GE3_S1 and GE3_S2 of the bridge portion GE3 in the first direction D1 may increase as a level is lowered.

The first and second side surfaces GE3_S1 and GE3_S2 of the bridge portion GE3 may be inclined at an angle with respect to the top surface GE3_U of the bridge portion GE3, the top surface GE1_U of the first channel overlap portion GE1, and the top surface GE2_U of the second channel overlap portion GE2. In the cross-sectional view illustrating FIG. 1E, an angle between the first side surface GE3_S1 of the bridge portion GE3 and the top surface GE1_U of the first channel overlap portion GE1 and an angle between the second side surface GE3_S2 of the bridge portion GE3 and the top surface GE2_U of the second channel overlap portion GE2 may be greater than 90°. In the cross-sectional view illustrating FIG. 1E, an angle between the first side surface GE3_S1 and the top surface GE3_U of the bridge portion GE3 and an angle between the second side surface GE3_S2 and the top surface GE3_U of the bridge portion GE3 may be smaller than 270°.

A width W1 of the bridge portion GE3 in the first direction D1 may increase as a level is lowered. The width W1 of the bridge portion GE3 in the first direction D1 may increase as a distance to the channel structure CH1 or CH2 decreases. The width W1 of the bridge portion GE3 in the first direction D1 may be smaller than a sum of widths of the first channel structure CH1, the second channel structure CH2, and the separation insulating layer 20 measured in the first direction D1.

The bridge portion GE3 may overlap the separation insulating layer 20 in the third direction D3. The separation insulating layer 20 may include a first portion P1, which overlaps the bridge portion GE3 of the gate electrode GE in the third direction D3, and a second portion P2, which is provided between the first and second source/drain structures SS1 and SS2. The second portion P2 of the separation insulating layer 20 might not overlap the bridge portion GE3 of the gate electrode GE in the third direction D3.

A top surface LAC_U of the lower portion LAC of the first active contact AC1, a top surface LAC_U of the lower portion LAC of the second active contact AC2, the top surface GE1_U of the first channel overlap portion GE1, the top surface GE2_U of the second channel overlap portion GE2, a top surface 14_U of the gate cutting insulating layer 14 (e.g., see FIGS. 1B and 1C), and a top surface P2_U of the second portion P2 of the separation insulating layer 20 may be located at the same level. The top surface LAC_U of the lower portion LAC of the first active contact AC1, the top surface GE1_U of the first channel overlap portion GE1, and the top surface 14_U of the gate cutting insulating layer 14 may be coplanar with each other. The top surface LAC_U of the lower portion LAC of the first active contact AC1, the top surface LAC_U of the lower portion LAC of the second active contact AC2, and the top surface P2_U of the second portion P2 of the separation insulating layer 20 may be coplanar with each other.

A level of a top surface P1_U of the first portion P1 of the separation insulating layer 20 may be higher than a level of the top surface LAC_U of the lower portion LAC of the first active contact AC1, a level of the top surface LAC_U of the lower portion LAC of the second active contact AC2, a level of the top surface GE1_U of the first channel overlap portion GE1, a level of the top surface GE2_U of the second channel overlap portion GE2, a level of the top surface 14_U of the gate cutting insulating layer 14, and a level of the top surface P2_U of the second portion P2 of the separation insulating layer 20.

A level of the top surface GE3_U of the bridge portion GE3 may be higher than a level of the top surface P1_U of the first portion P1 of the separation insulating layer 20, a level of the top surface P2_U of the second portion P2 of the separation insulating layer 20, a level of the top surface LAC_U of the lower portion LAC of the first active contact AC1, a level of the top surface LAC_U of the lower portion LAC of the second active contact AC2, a level of the top surface GE1_U of the first channel overlap portion GE1, a level of the top surface GE2_U of the second channel overlap portion GE2, and a level of the top surface 14_U of the gate cutting insulating layer 14.

The bridge insulating layer 23 may include a first side surface 23_S1 in contact with the capping insulating layer 21 and a second side surface 23_S2 in contact with the lower portion 31 of the gate connection pattern 30. The first and second side surfaces 23_S1 and 23_S2 of the bridge insulating layer 23 may be opposite to each other. The first side surface 23_S1 of the bridge insulating layer 23 may be coplanar with the first side surface GE3_S1 of the bridge portion GE3. The first side surface 23_S1 of the bridge insulating layer 23 may be inclined at an angle with respect to top and bottom surfaces of the bridge insulating layer 23.

The capping insulating layer 21 may include a first side surface 21_S1, which is in contact with the first side surface 23_S1 of the bridge insulating layer 23 and the first side surface GE3_S1 of the bridge portion GE3, and a second side surface 21_S2, which is in contact with the lower portion 31 of the gate connection pattern 30 and the second side surface GE3_S2 of the bridge portion GE3. The first and second side surfaces 21_S1 and 21_S2 of the capping insulating layer 21 may be inclined at an angle with respect to top and bottom surfaces of the capping insulating layer 21.

A width W2 of the lower portion 31 of the gate connection pattern 30 in the first direction D1 may increase as a level is lowered. A width W3 of the upper portion 32 of the gate connection pattern 30 in the first direction D1 may decrease as a level is lowered. The width W2 of the lower portion 31 of the gate connection pattern 30 in the first direction D1 and the width W3 of the upper portion 32 of the gate connection pattern 30 in the first direction D1 may be smaller than the width W1 of the bridge portion GE3 in the first direction D1.

A bottom surface of the lower portion 31 of the gate connection pattern 30 may be in contact with the top surface GE3_U of the bridge portion GE3. The lower portion 31 of the gate connection pattern 30 may include a first side surface 31_S1 in contact with the second side surface 23_S2 of the bridge insulating layer 23 and a second side surface 31_S2 in contact with the second side surface 21_S2 of the capping insulating layer 21. The first side surface 31_S1 of the lower portion 31 of the gate connection pattern 30 may be connected to a top surface GE_U of the bridge portion GE3. The second side surface 31_S2 of the lower portion 31 of the gate connection pattern 30 may be connected to the top surface GE_U and the second side surface GE3_S2 of the bridge portion GE3. There may be a triple point, at which the top surface GE3_U of the bridge portion GE3, the second side surface GE3_S2 of the bridge portion GE3, and the second side surface 31_S2 of the lower portion 31 of the gate connection pattern 30 are connected to each other. The second side surface 31_S2 of the lower portion 31 of the gate connection pattern 30 may be coplanar with the second side surface GE3_S2 of the bridge portion GE3. A side surface 32_S of the upper portion 32 of the gate connection pattern 30 may be connected to the side surfaces 31_S1 and 31_S2 of the lower portion 31 of the gate connection pattern 30.

The bridge portion GE3 may include a first portion Gl connected to the first channel overlap portion GE1, a second portion G2 connected to the second channel overlap portion GE2, and a third portion G3 between the first and second portions G1 and G2. The third portion G3 of the bridge portion GE3 may overlap the first portion P1 of the separation insulating layer 20 in the third direction D3.

The first portion G1 of the bridge portion GE3 may be provided between the third portion G3 of the bridge portion GE3 and the first channel overlap portion GE1. The second portion G2 of the bridge portion GE3 may be provided between the third portion G3 of the bridge portion GE3 and the second channel overlap portion GE2. The first side surface GE3_S1 of the bridge portion GE3 may be a side surface of the first portion G1 of the bridge portion GE3. The second side surface GE3_S2 of the bridge portion GE3 may be a side surface of the second portion G2 of the bridge portion GE3. The lower portion 31 of the gate connection pattern 30 may be in contact with a top surface of the second portion G2 of the bridge portion GE3. In an embodiment, the lower portion 31 of the gate connection pattern 30 may be in contact with a top surface of the first or third portion G1 or G3 of the bridge portion GE3.

The width of the gate connection pattern 30 in the first direction D1 may be smaller than a width of the second portion G2 of the bridge portion GE3 in the first direction D1. A bottom surface of the bridge insulating layer 23 may be in contact with top surfaces of the first to third portions G1, G2, and G3 of the bridge portion GE3. A width of each of the first and second portions G1 and G2 of the bridge portion GE3 in the first direction D1 may increase as a level is lowered.

The third portion G3 of the bridge portion GE3 may be disposed at a level that is higher than the top surface P1_U of the first portion P1 of the separation insulating layer 20. The first channel overlap portion GE1, the second channel overlap portion GE2, a portion of the first portion G1 of the bridge portion GE3, and a portion of the second portion G2 of the bridge portion GE3 may be disposed at a level that is lower than the top surface P1_U of the first portion P1 of the separation insulating layer 20.

The first portion G1 of the bridge portion GE3 may include a side surface G1_S in contact with the gate insulating layer GI. The second portion G2 of the bridge portion GE3 may include a side surface G2_S in contact with the gate insulating layer GI. A bottom surface G3_L of the third portion G3 of the bridge portion GE3 may be in contact with the gate insulating layer GI.

A side surface UAC_S of the upper portion UAC of the first active pattern AC1 may be coplanar with a side surface 41_S of the lower portion 41 of the contact connection pattern 40. A bottom surface of the lower portion 41 of the contact connection pattern 40 may be in contact with a top surface UAC_U of the upper portion UAC of the first active pattern AC1. A width W4 of the upper portion UAC of the first active pattern AC1 in the first direction D1 may increase as a level is lowered. A width W5 of the lower portion 41 of the contact connection pattern 40 in the first direction D1 may increase as a level is lowered. A width W6 of the upper portion 42 of the contact connection pattern 40 in the first direction D1 may decrease as a level is lowered.

The capping insulating layer 21 may include a third side surface 21_S3 in contact with the side surface UAC_S of the upper portion UAC of the first active pattern AC1 and the side surface 41_S of the lower portion 41 of the contact connection pattern 40.

In an embodiment, a distance between the uppermost portion of the channel structure CH1 or CH2 and the top surface GE_U of the bridge portion GE3 in the third direction D3 may range from 1 nm to 30 nm. A thickness of the third portion G3 of the bridge portion GE3 in the third direction D3 may be smaller than a thickness of the first and second portions G1 and G2 of the bridge portion GE3 in the third direction D3. In an embodiment, the thickness of the third portion G3 of the bridge portion GE3 in the third direction D3 may range from 1 nm to 20 nm. The width W1 of the bridge portion GE3 in the first direction D1 may be 1 nm to 20 nm larger than the width W2 of the lower portion 31 of the gate connection pattern 30 in the first direction D1. In an embodiment, a thickness of the lower portion 31 of the gate connection pattern 30 in the third direction D3 may range from 1 nm to 20 nm.

In an embodiment, since the semiconductor device includes the bridge portion GE3 of the gate electrode GE and the gate connection pattern 30, it may be unnecessary to separately form a contact and a conductive line, which are connected to each of the first and second channel overlap portions GE1 and GE2. Thus, it may be possible to reduce the size and the fabrication cost of the semiconductor device. In addition, it may be possible to reduce technical difficulties in designing the conductive lines 24.

In an embodiment, since the bridge portion GE3 of the gate electrode GE has a relatively small width, a capacitance issue caused by the gate electrode GE may be reduced, and the electrical characteristics of the semiconductor device may be improved.

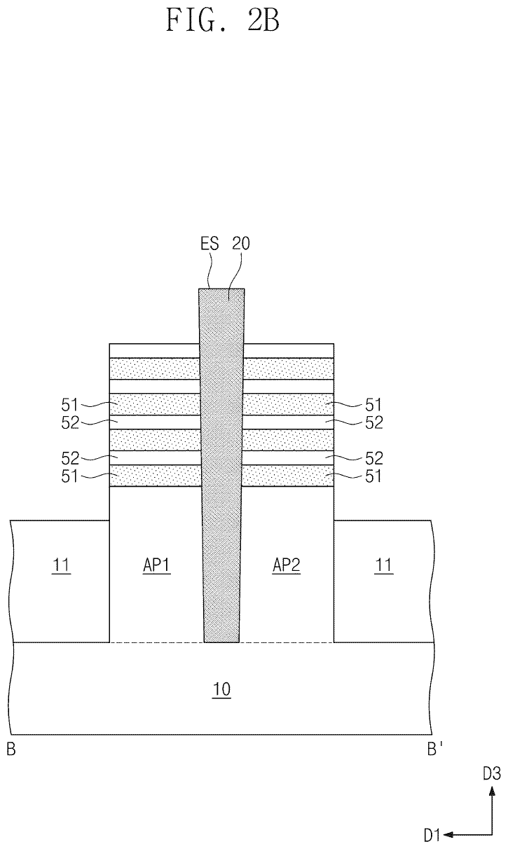

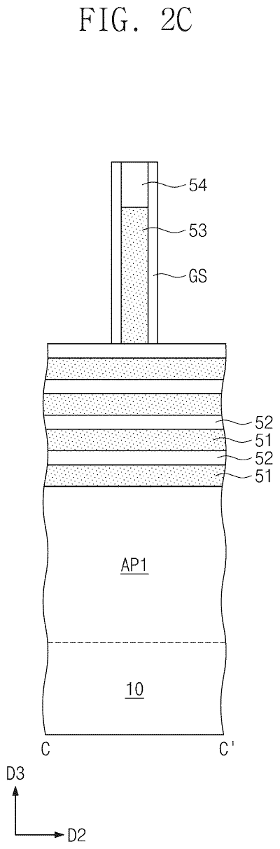

FIGS. 2A, 2B, 2C, 3A, 3B, 4A, 4B, 4C, 5A, 5B, 5C, 6A, 6B, 6C, 7A, 7B, 7C, 7D, 8A, 8B, 8C, 9A, 9B, 9C, 9D, 10A, 10B, 10C, 11A, 11B, and 11C are diagrams illustrating a method of fabricating the semiconductor device of FIGS. 1A to 1F.

Referring to FIGS. 2A, 2B, and 2c, the device isolation layer 11, the active patterns AP1 and AP2, sacrificial semiconductor layers 51, semiconductor layers 52, and the separation insulating layer 20 may be formed. The formation of the device isolation layer 11, the active patterns AP1 and AP2, the sacrificial semiconductor layers 51, the semiconductor layers 52, and the separation insulating layer 20 may include alternatingly forming preliminary sacrificial semiconductor layers and preliminary semiconductor layers on a substrate 100, patterning the substrate 100, the preliminary sacrificial semiconductor layers, and the preliminary semiconductor layers to form preliminary active patterns, the sacrificial semiconductor layers 51, and the semiconductor layers 52, forming the device isolation layer 11, and forming the separation insulating layer 20. The preliminary active pattern may be divided into the active patterns AP1 and AP2 by the separation insulating layer 20.

The sacrificial semiconductor layer 51 may include a material having an etch selectivity with respect to the semiconductor layer 52. For example, the sacrificial semiconductor layer 51 may be formed of or otherwise include silicon-germanium (SiGe), and the semiconductor layer 52 may be formed of or otherwise include silicon (Si).

A gate sacrificial pattern 53, a gate mask pattern 54, and the gate spacers GS may be formed. The formation of the gate sacrificial pattern 53, the gate mask pattern 54, and the gate spacers GS may include forming a preliminary gate sacrificial layer disposed on the semiconductor layers 52 and the sacrificial semiconductor layers 51, forming the gate mask pattern 54 on the preliminary gate sacrificial layer, etching the preliminary gate sacrificial layer using the gate mask pattern 54 as an etch mask to form the gate sacrificial pattern 53, and forming the gate spacers GS.

The gate sacrificial pattern 53 and the gate mask pattern 54 may extend in the first direction D1. In an embodiment, the gate sacrificial pattern 53 may be formed of or otherwise include poly silicon. The gate mask pattern 54 may include an insulating material.

The separation insulating layer 20 may include an exposed top surface ES. The exposed top surface ES of the separation insulating layer 20 might not be covered with the gate sacrificial pattern 53 and may be externally exposed.

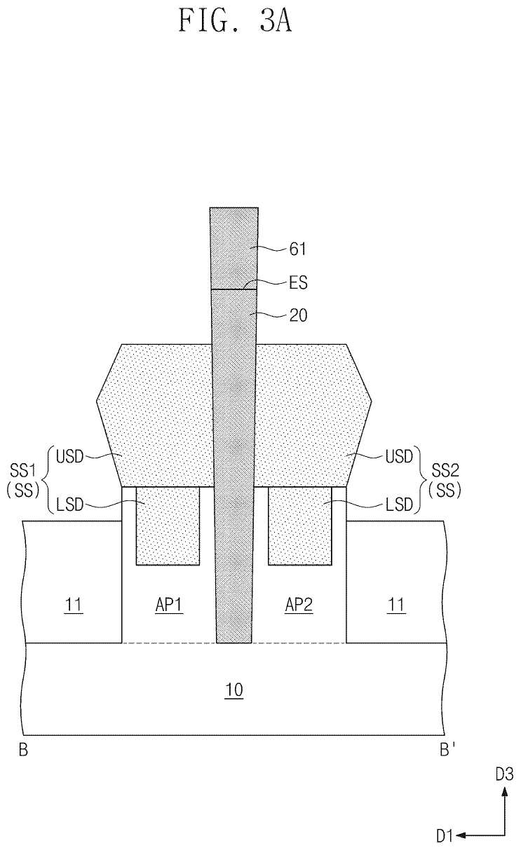

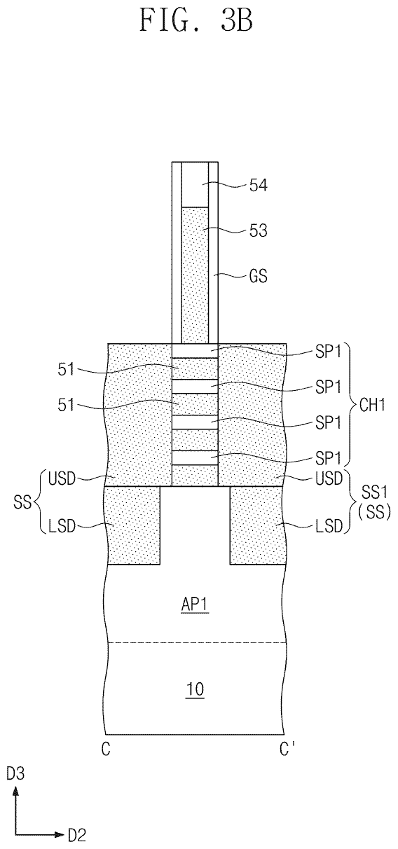

Referring to FIGS. 3A and 3B, the sacrificial semiconductor layers 51, the semiconductor layers 52, and the active patterns AP1 and AP2 may be etched using the gate mask pattern 54 and the gate spacer GS as an etch mask. As a result of the etching process, the semiconductor layer 52 may be divided into the semiconductor patterns SP1 and SP2.

A sacrificial insulating layer 61 may be formed on the separation insulating layer 20. The sacrificial insulating layer 61 may be formed on the exposed top surface ES of the separation insulating layer 20. The sacrificial insulating layer 61 may include an insulating material.

The lower source/drain patterns LSD and the upper source/drain patterns USD may be formed. The lower source/drain pattern LSD may be formed in an empty space, which is formed by etching the active pattern AP1 or AP2. The upper source/drain pattern USD may be formed in an empty space, which is formed by etching the sacrificial semiconductor layers 51 and the semiconductor layers 52.

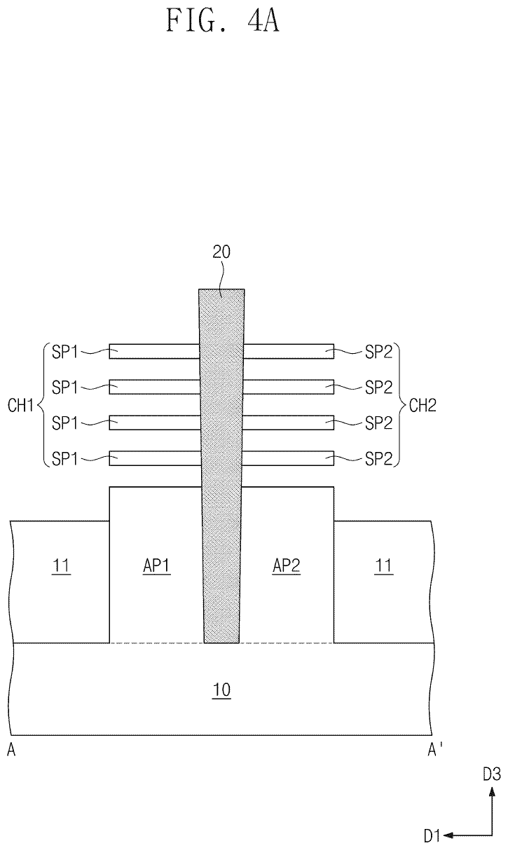

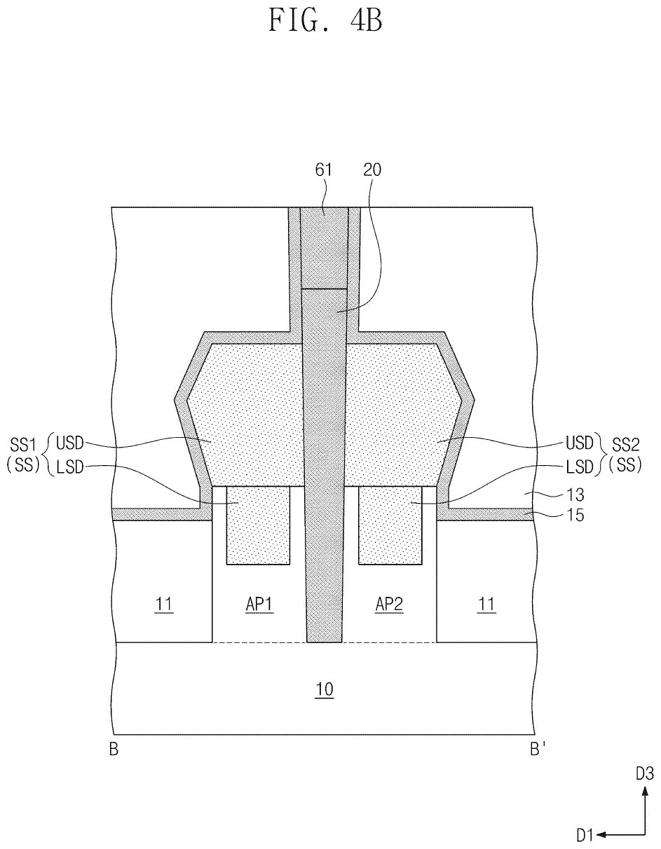

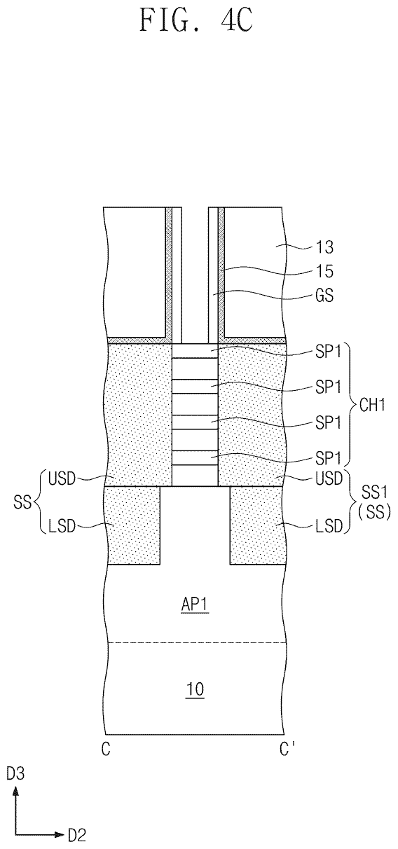

Referring to FIGS. 4A, 4B, and 4C, the cover insulating layer 15 and the insulating layer 13 may be formed.

The gate mask pattern 54, the gate sacrificial pattern 53, and the sacrificial semiconductor layers 51 may be removed.

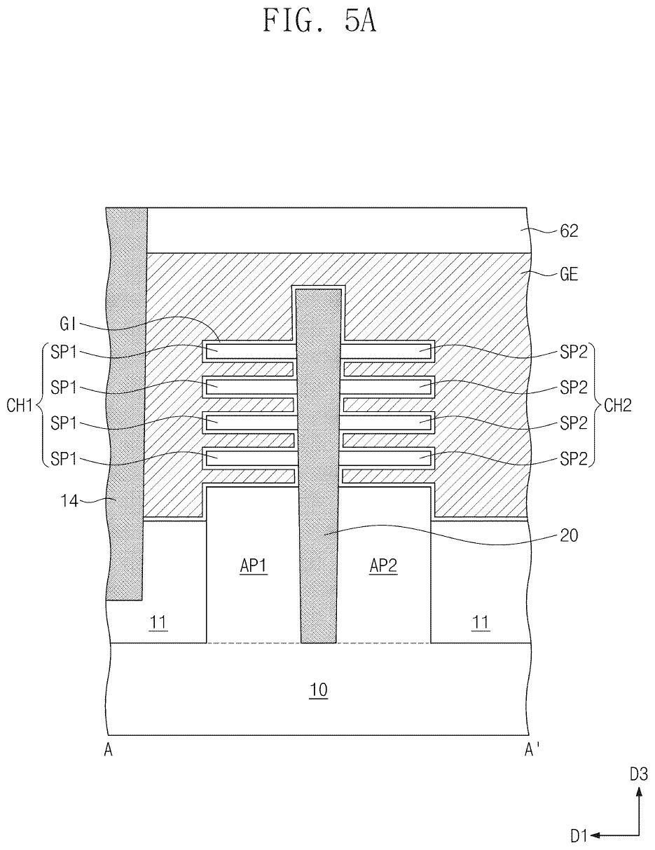

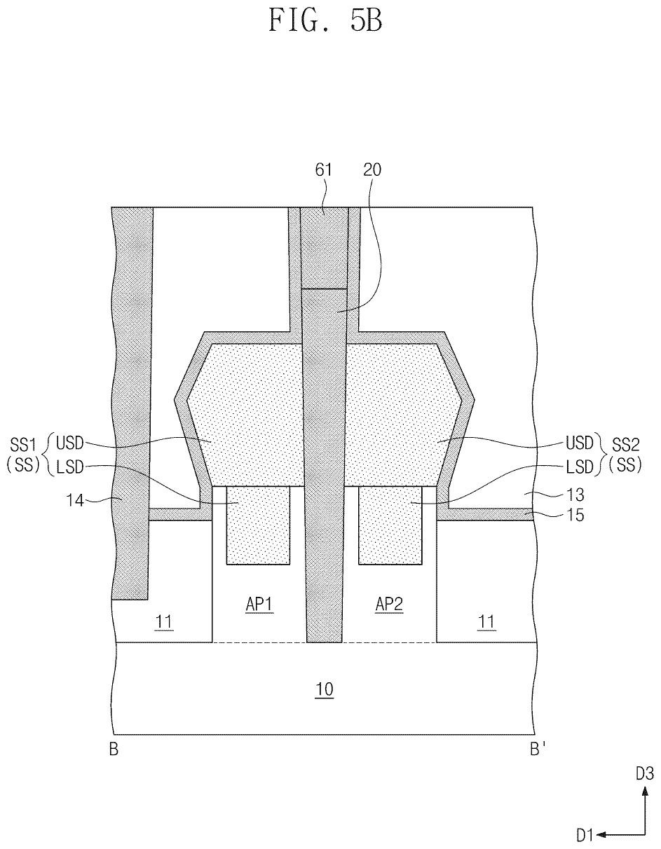

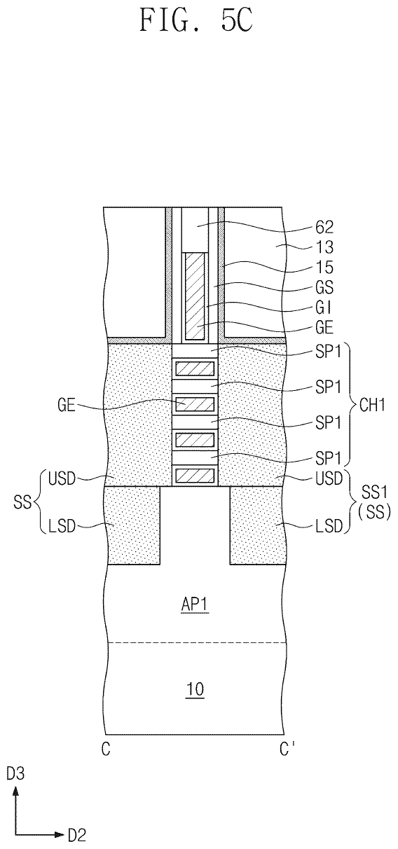

Referring to FIGS. 5A, 5B, and 5C, the gate insulating layer GI and the gate electrode GE may be formed. The gate insulating layer GI and the gate electrode GE may be formed in empty spaces, which are formed by removing the gate sacrificial pattern 53 and the sacrificial semiconductor layers 51. A gate capping layer 62 may be formed on the gate electrode GE. The gate capping layer 62 may include an insulating material.

The gate cutting insulating layer 14 may be formed. The gate cutting insulating layer 14 may penetrate the gate capping layer 62 and the gate electrode GE. The gate electrode GE may be divided into a plurality of gate electrodes GE by the gate cutting insulating layer 14.

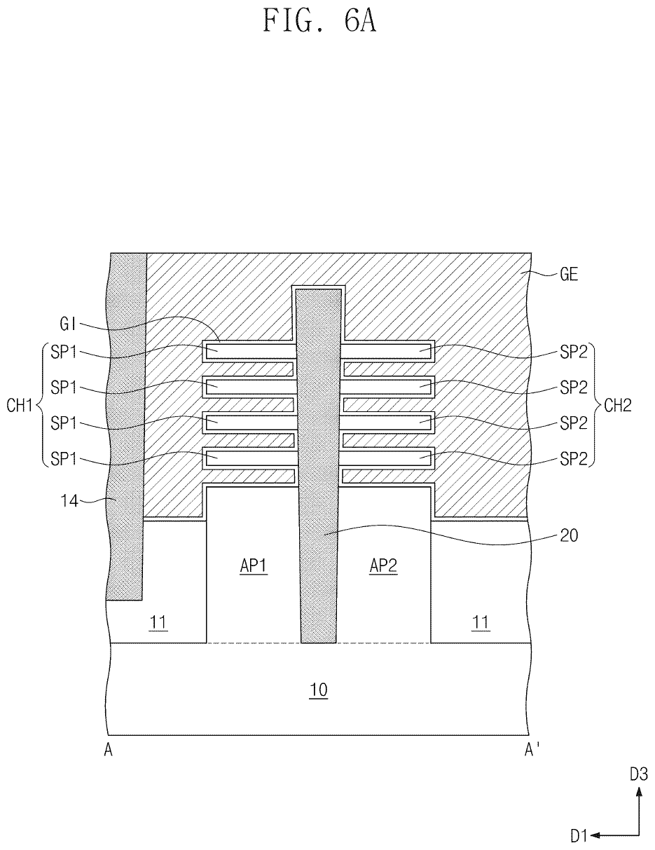

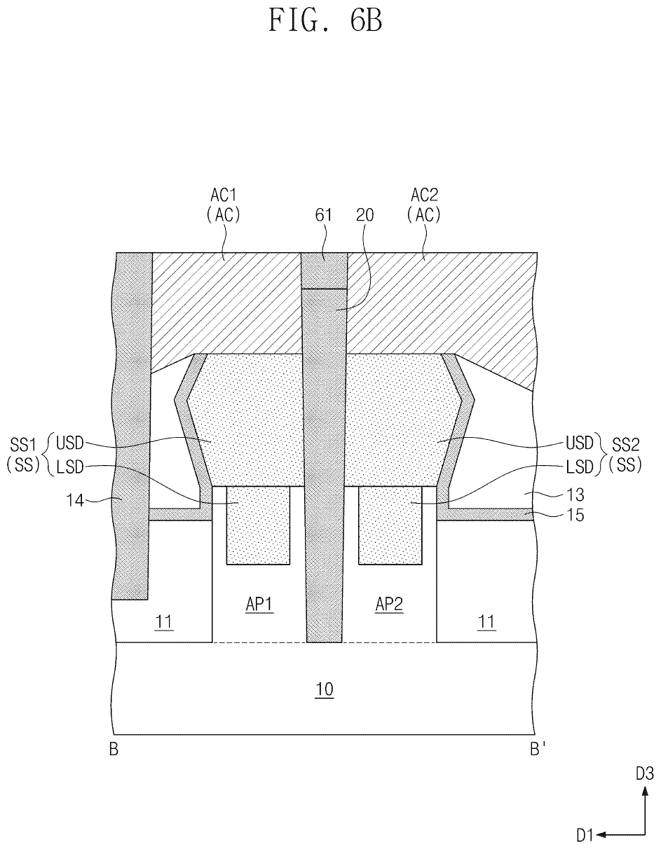

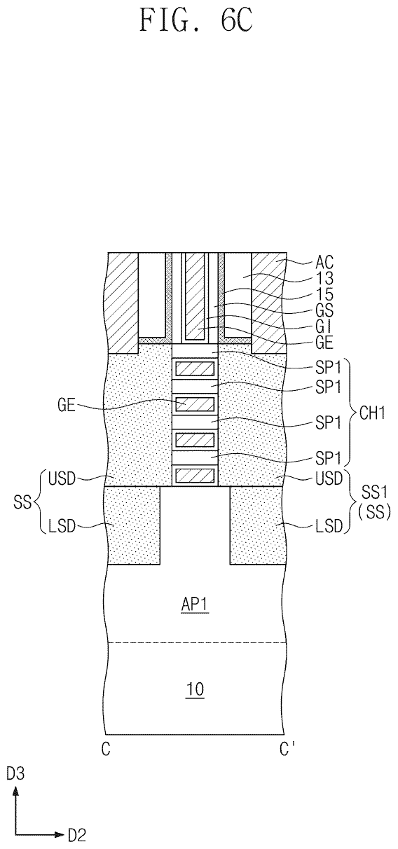

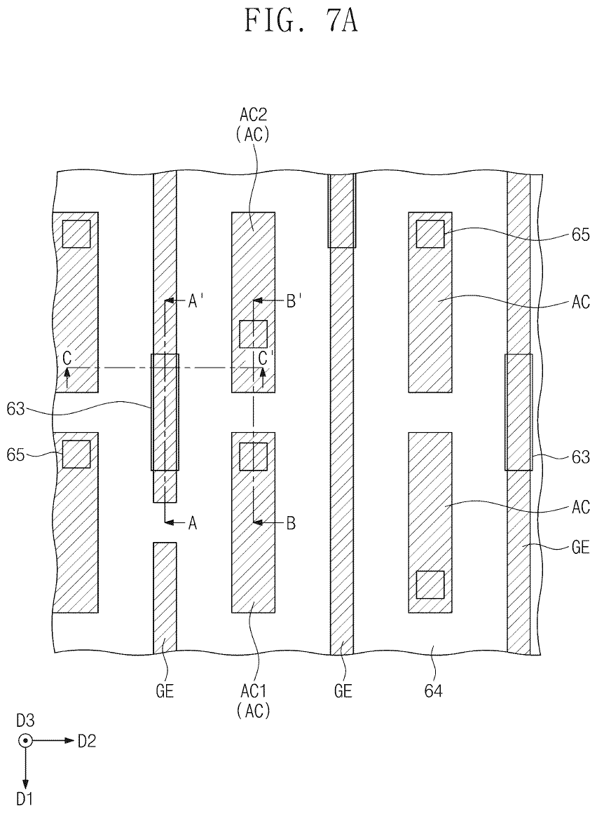

Referring to FIGS. 6A, 6B, and 6C, the insulating layer 13 and the cover insulating layer 15 may be etched to expose the upper source/drain patterns USD. A preliminary contact layer may cover the upper source/drain patterns USD that are exposed. An upper portion of the preliminary contact layer and the gate capping layer 62 may be removed. In an embodiment, the upper portion of the preliminary contact layer and the gate capping layer 62 may be removed by a chemical mechanical polishing (CMP) process. In an embodiment, an upper portion of the sacrificial insulating layer 61 may be removed, during the removal of the upper portion of the preliminary contact layer and the gate capping layer 62.

As a result of the removal of the upper portion of the preliminary contact layer, the active contacts AC may be formed. As a result of the removal of the upper portion of the preliminary contact layer, the preliminary contact layer may be divided into the active contacts AC. As a result of the removal of the gate capping layer 62, the gate electrode GE may be exposed.

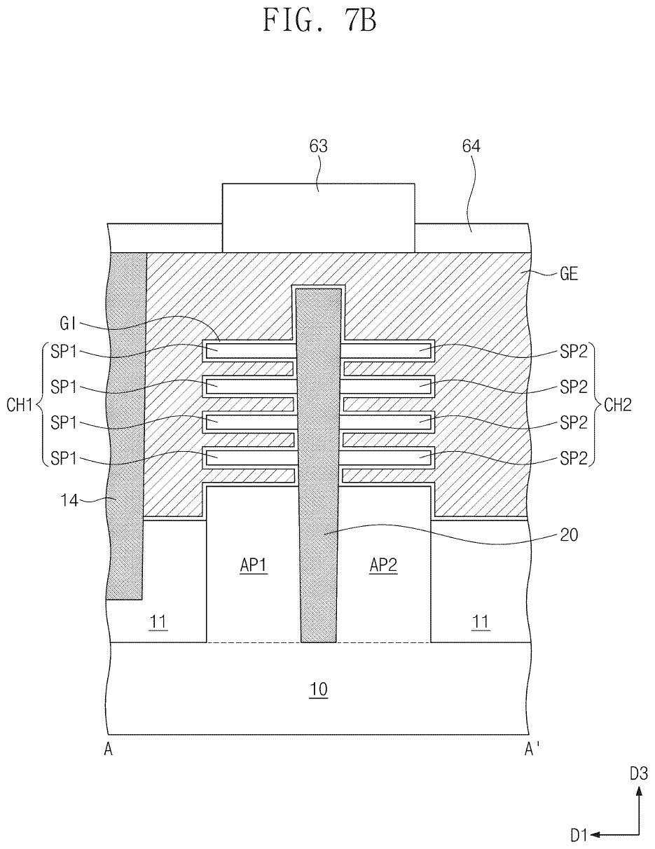

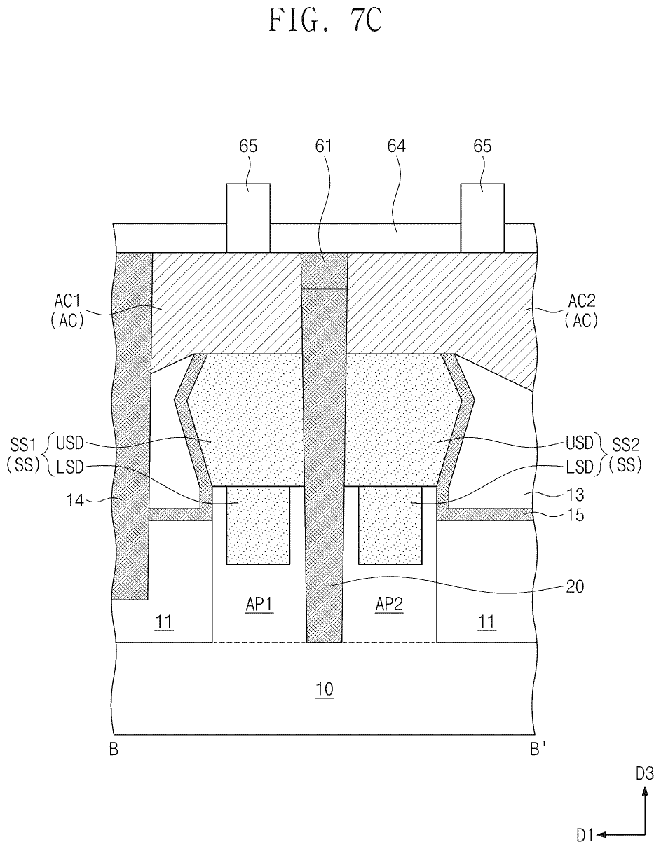

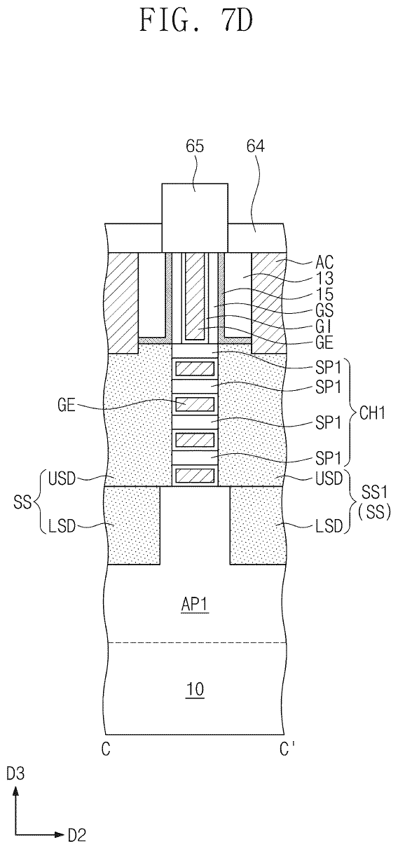

Referring to FIGS. 7A, 7B, 7C, and 7D, a mask layer 64 may be formed on the gate electrode GE and the active contact AC. The mask layer 64 may include an insulating material. In an embodiment, the mask layer 64 may include a nitride material.

A bridge sacrificial pattern 63 and a contact sacrificial pattern 65 may penetrate the mask layer 64. The bridge sacrificial pattern 63 may overlap the gate electrode GE in the third direction D3. The contact sacrificial pattern 65 may overlap the active contact AC in the third direction D3. The bridge sacrificial pattern 63 and the contact sacrificial pattern 65 may include an insulating material. In an embodiment, the bridge sacrificial pattern 63 and the contact sacrificial pattern 65 may include an oxide material.

A thickness of the bridge sacrificial pattern 63 and the contact sacrificial pattern 65 in the third direction D3 may be larger than a thickness of the mask layer 64 in the third direction D3. A level of top surfaces of the bridge sacrificial pattern 63 and the contact sacrificial pattern 65 may be higher than a level of a top surface of the mask layer 64. In an embodiment, the bridge sacrificial pattern 63 and the contact sacrificial pattern 65 may be formed at the same time.

A width of the bridge sacrificial pattern 63 in the first direction D1 may be smaller than a width of the gate electrode GE in the first direction D1. A width of the bridge sacrificial pattern 63 in the second direction D2 may be larger than a width of the gate electrode GE in the second direction D2.

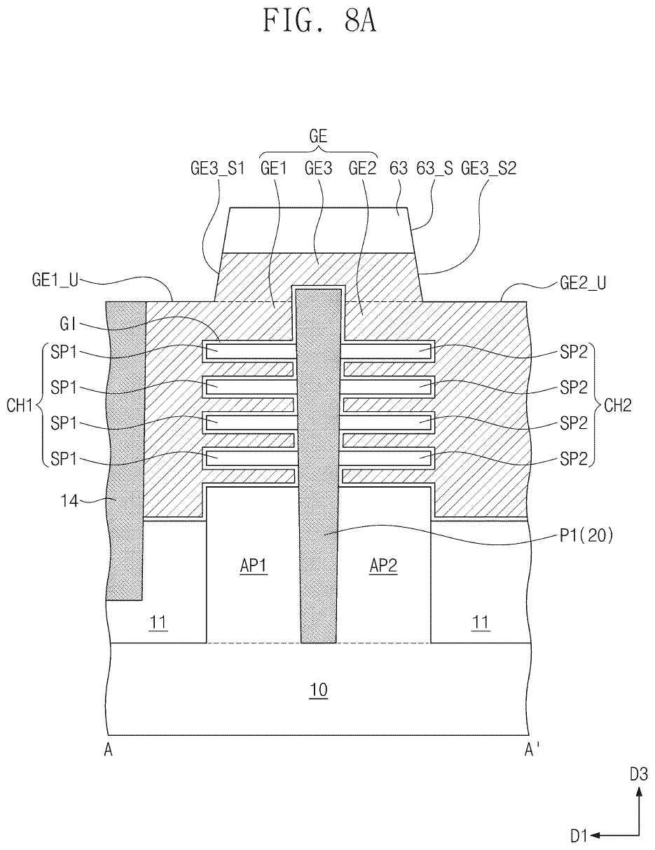

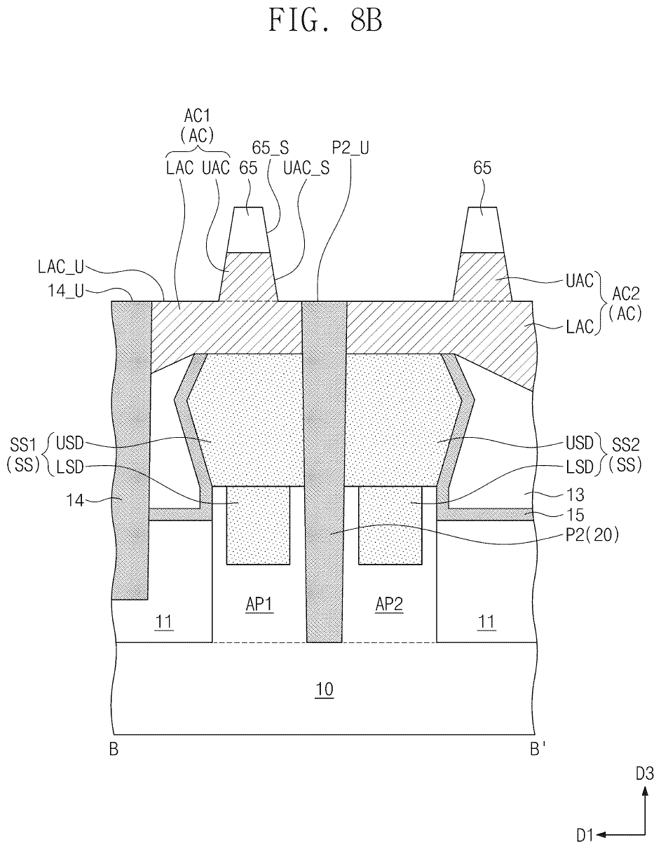

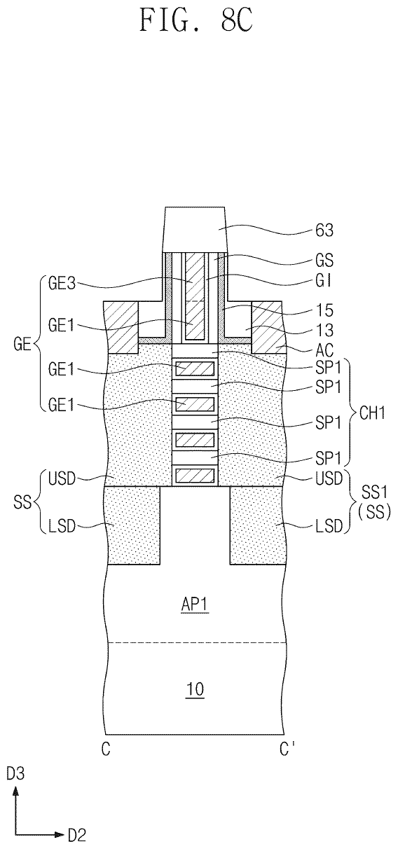

Referring to FIGS. 8A, 8B, and 8C, the mask layer 64, the gate electrode GE, the gate cutting insulating layer 14, the separation insulating layer 20, and the active contact AC may be etched using the bridge sacrificial pattern 63 and the contact sacrificial pattern 65 as an etch mask. In an embodiment, the mask layer 64, the gate electrode GE, the gate cutting insulating layer 14, the separation insulating layer 20 and the active contact AC may be etched by a non-selective etching process.

As a result of the etching of the gate electrode GE, the first channel overlap portion GE1, the second channel overlap portion GE2, and the bridge portion GE3 of the gate electrode GE may be formed. The bridge portion GE3 may be a portion of the gate electrode GE, which is unetched in the etching process due to the bridge sacrificial pattern 63. A side surface 63_S of the bridge sacrificial pattern 63 may be coplanar with side surfaces GE3_S1 and GE3_S2 of the bridge portion GE3. The side surface 63_S of the bridge sacrificial pattern 63 may be inclined at an angle with respect to top and bottom surfaces of the bridge sacrificial pattern 63. The width of the bridge sacrificial pattern 63 in the first direction D1 may increase as a level is lowered.

As a result of the etching of the active contact AC, the lower and upper portions LAC and UAC of the active contact AC may be formed. The upper portion UAC of the active contact AC may be a portion of the active contact AC, which is unetched in the etching process due to the contact sacrificial pattern 65. A side surface 65_S of the contact sacrificial pattern 65 may be coplanar with the side surface UAC_S of the upper portion UAC of the active contact AC. The side surface 65_S of the contact sacrificial pattern 65 may be inclined at an angle with respect to top and bottom surfaces of the contact sacrificial pattern 65. A width of the contact sacrificial pattern 65 in the first direction D1 may increase as a level is lowered.

The first portion P1 of the separation insulating layer 20 may overlap the bridge sacrificial pattern 63 in the third direction D3. The first portion P1 of the separation insulating layer 20 may be protected from the etching process, due to the bridge sacrificial pattern 63 and the bridge portion GE3. The mask layer 64 may be removed by the etching process, and in this case, the second portion P2 of the separation insulating layer 20 may be exposed and etched. As a result of the etching of the second portion P2 of the separation insulating layer 20, the top surface P2_U of the second portion P2 of the separation insulating layer 20 may be defined.

As a result of the etching of the mask layer 64, the gate cutting insulating layer 14 may be exposed and etched. As a result of the etching of the gate cutting insulating layer 14, the top surface 14_U of the gate cutting insulating layer 14 may be defined.

As a result of the etching process, the top surface 14_U of the gate cutting insulating layer 14, the top surface P2_U of the second portion P2 of the separation insulating layer 20, the top surfaces GE1_U and GE2_U of the first and second channel overlap portions GE1 and GE2, and the top surface LAC_U of the lower portion LAC of the active contact AC may be coplanar with each other.

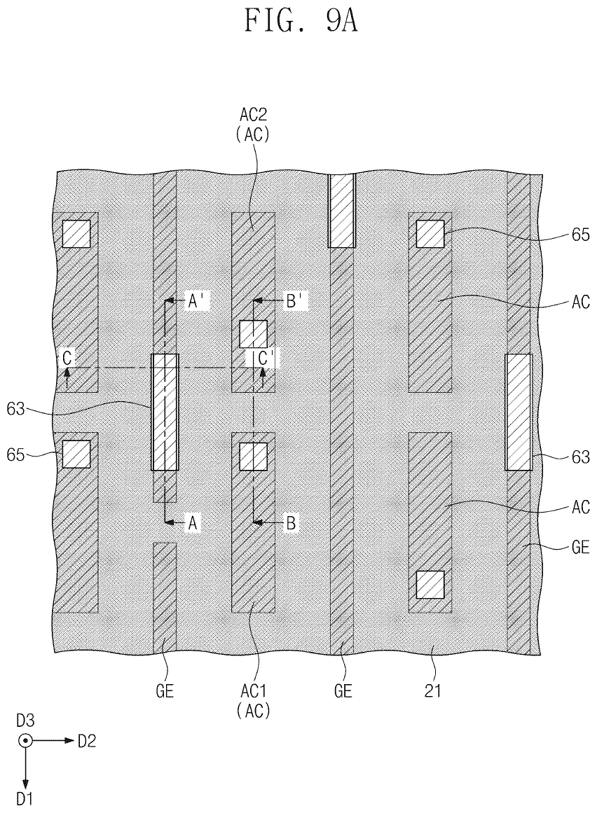

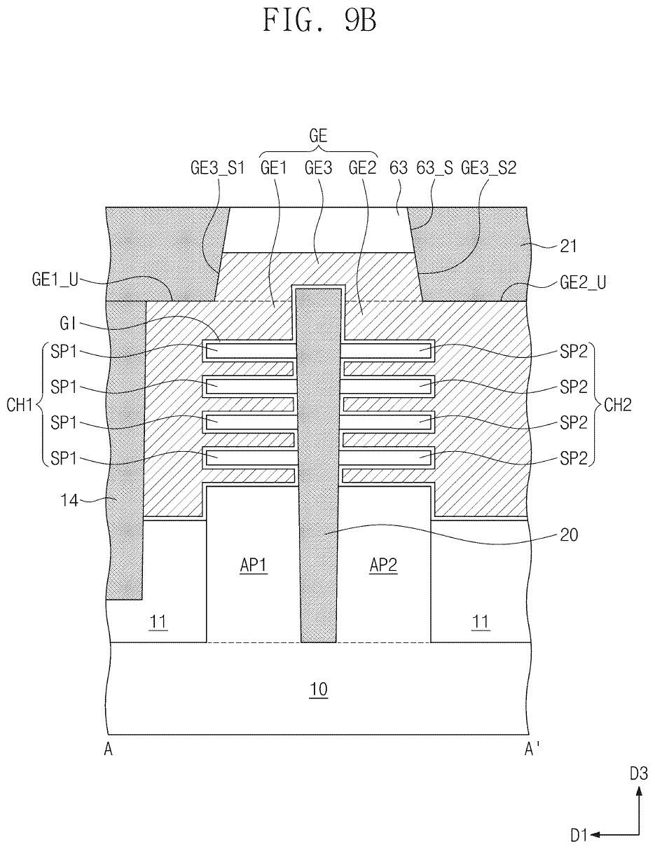

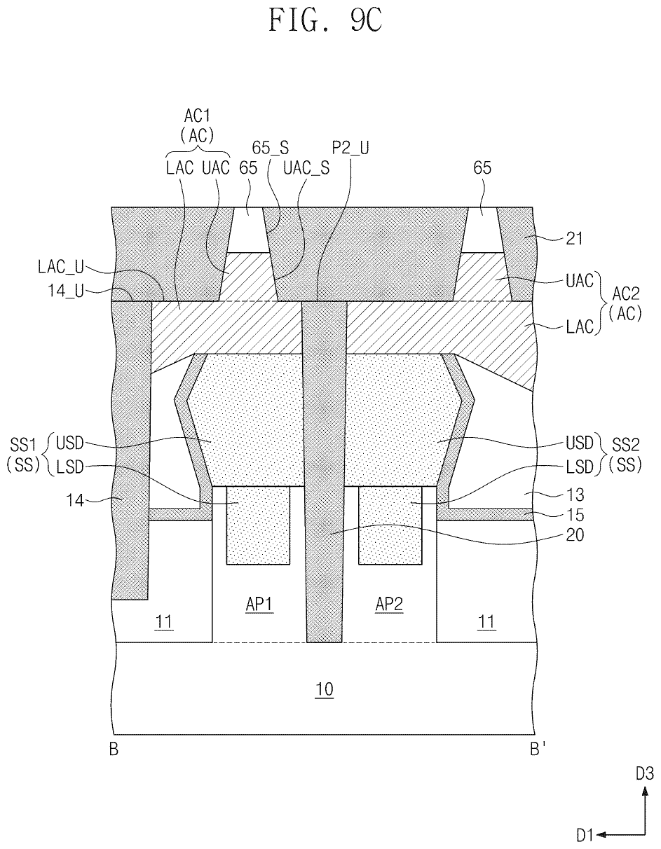

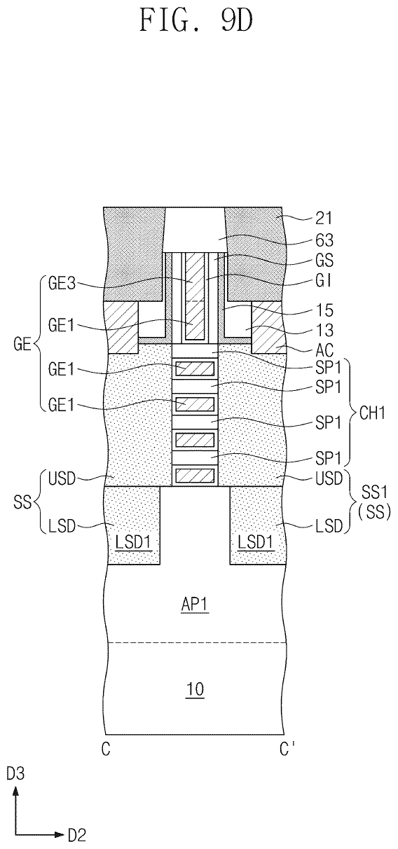

Referring to FIGS. 9A, 9B, 9C, and 9D, the capping insulating layer 21 may be formed. The capping insulating layer 21 may enclose the bridge portion GE3, the upper portion UAC of the active contact AC, the bridge sacrificial pattern 63, and the contact sacrificial pattern 65. The capping insulating layer 21 may be in contact with the top surface 14_U of the gate cutting insulating layer 14, the top surface P2_U of the second portion P2 of the separation insulating layer 20, the top surfaces GE1_U and GE2_U of the first and second channel overlap portions GE1 and GE2, the top surface LAC_U of the lower portion LAC of the active contact AC, the side surfaces GE3_S1 and GE3_S2 of the bridge portion GE3, the side surface 63_S of the bridge sacrificial pattern 63, the side surface UAC_S of the upper portion UAC of the active contact AC, and the side surface 65_S of the contact sacrificial pattern 65.

A top surface of the capping insulating layer 21, a top surface of the bridge sacrificial pattern 63, and a top surface of the contact sacrificial pattern 65 may be coplanar with each other. In an embodiment, the formation of the capping insulating layer 21 may include forming a preliminary capping insulating layer and removing an upper portion of the preliminary capping insulating layer to form the capping insulating layer 21.

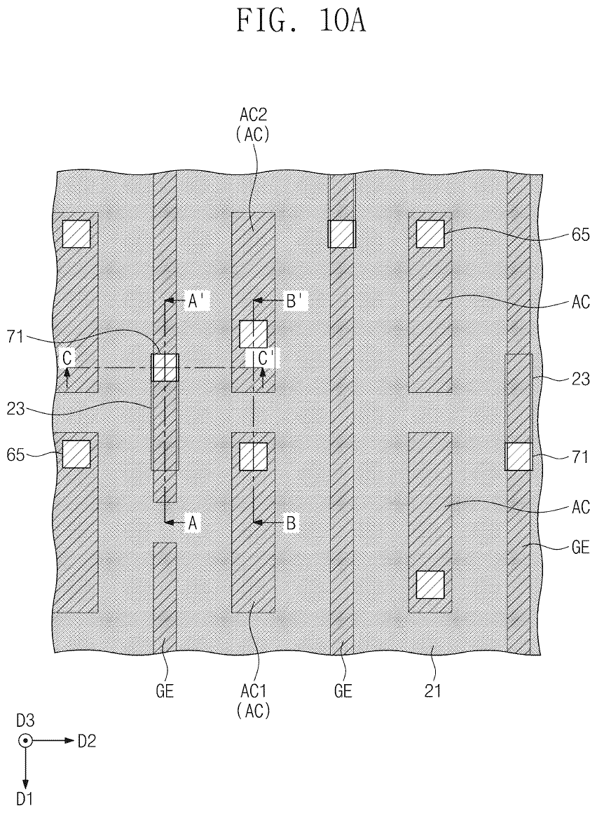

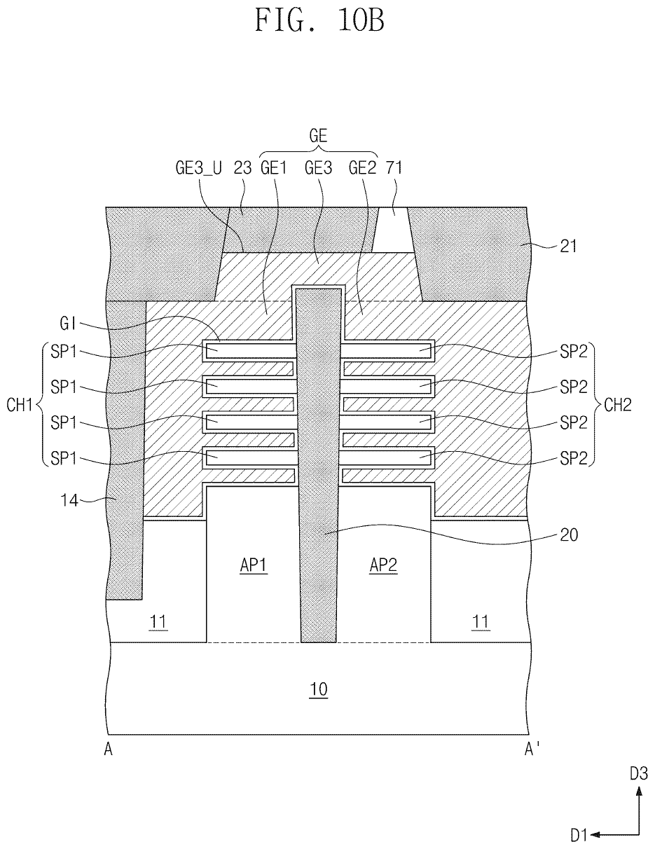

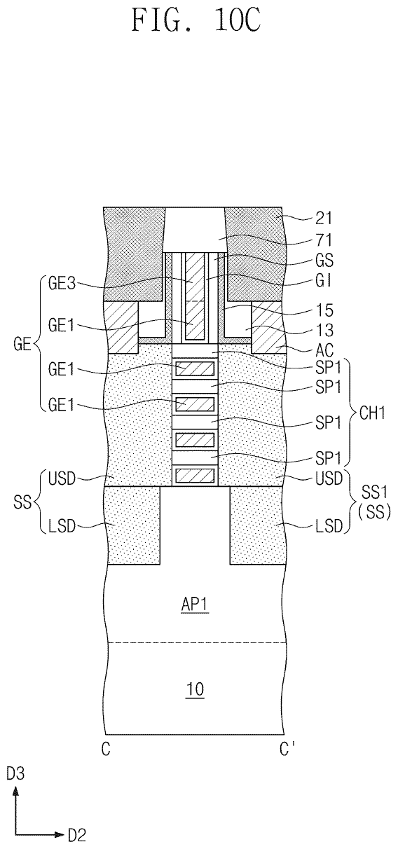

Referring to FIGS. 10A, 10B, and 10C, the bridge sacrificial pattern 63 may be selectively etched. As a result of the etching of the bridge sacrificial pattern 63, a gate sacrificial pattern 71 may be formed. A remaining portion of the bridge sacrificial pattern 63, which is unetched by the etching process, may be defined as the gate sacrificial pattern 71.

As a result of the etching of the bridge sacrificial pattern 63, the top surface GE3_U of the bridge portion GE3 may be exposed. The bridge insulating layer 23 may be formed on the top surface GE3_U of the bridge portion GE3. The bridge insulating layer 23 may cover the top surface GE3_U of the bridge portion GE3.

A width of the gate sacrificial pattern 71 in the first direction D1 may be smaller than a width of the bridge insulating layer 23 in the first direction D1. The width of the gate sacrificial pattern 71 in the first direction D1 may be smaller than a width of the bridge portion GE3 in the first direction D1. A width of the gate sacrificial pattern 71 in the second direction D2 may be equal to a width of the bridge insulating layer 23 in the second direction D2. The width of the gate sacrificial pattern 71 in the second direction D2 may be larger than a width of the bridge portion GE3 in the second direction D2. A portion of the top surface GE3_U of the bridge portion GE3 may be in contact with a bottom surface of the gate sacrificial pattern 71, and the other portion may be in contact with a bottom surface of the bridge insulating layer 23.

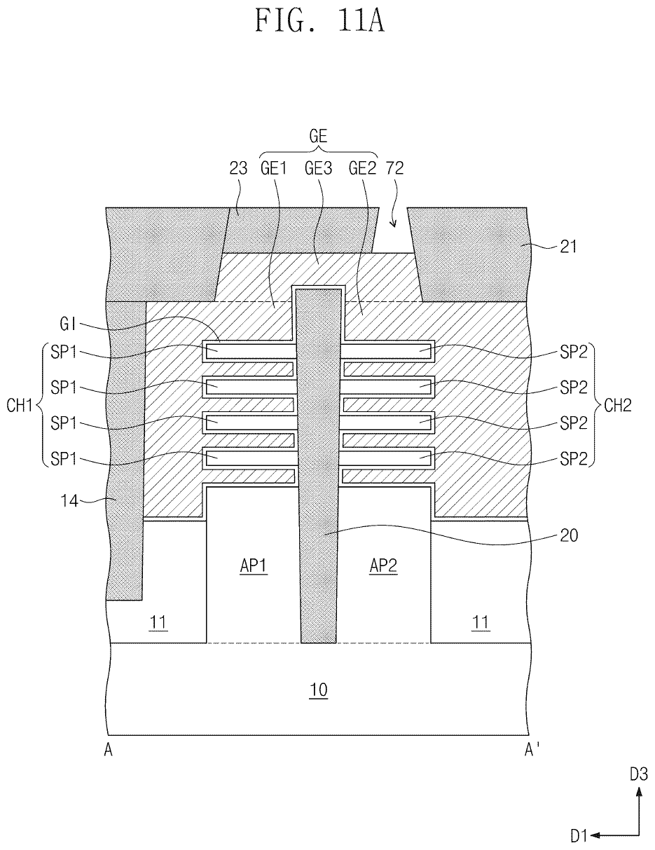

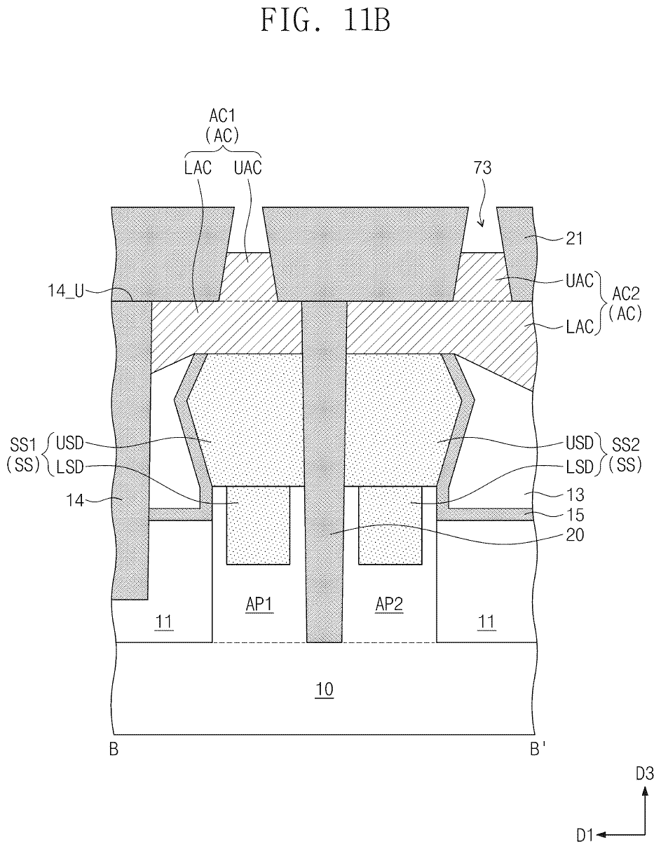

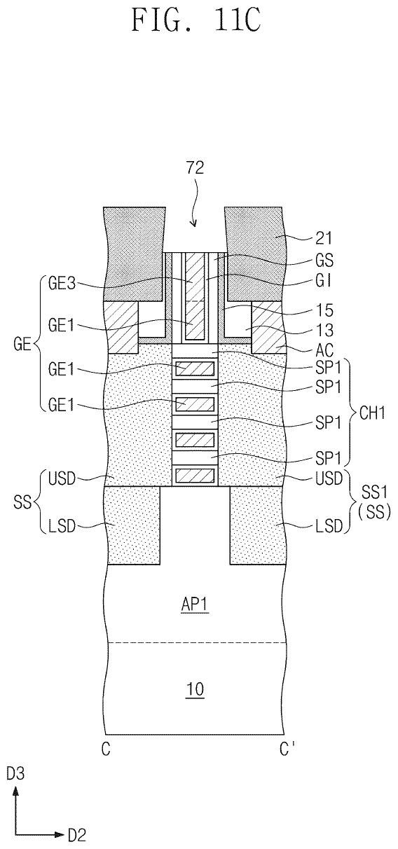

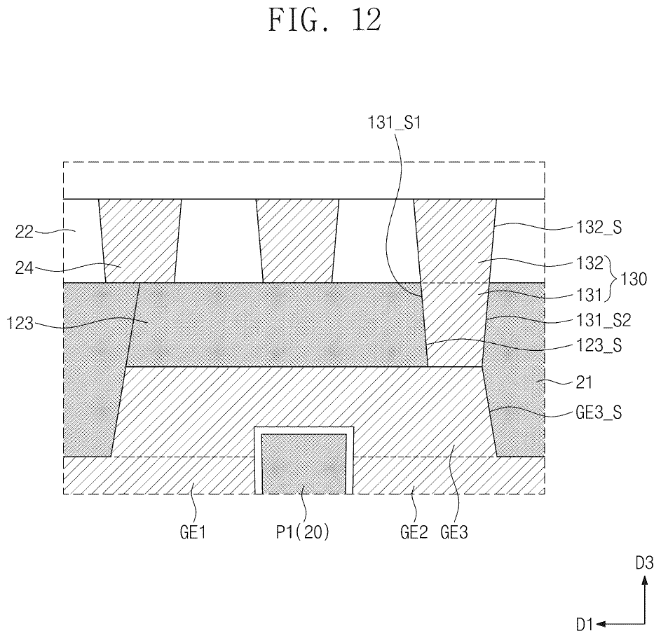

Referring to FIGS. 11A and 11B, the gate sacrificial pattern 71 and the contact sacrificial pattern 65 may be selectively removed. The gate sacrificial pattern 71 may be removed to form a first space 72. The first space 72 may be an empty space, which is formed by the removing of the gate sacrificial pattern 71. The first space 72 may expose the bridge portion GE3. The contact sacrificial pattern 65 may be removed to form a second space 73. The second space 73 may be an empty space, which is formed by the removing of the contact sacrificial pattern 65. The second space 73 may expose the upper portion UAC of the active contact AC.

Referring to FIGS. 1A to 1D, the upper insulating layer 22 may be formed. The upper insulating layer 22 may include a first portion filling the first space 72 and a second portion filling the second space 73.

The upper insulating layer 22 may be etched to form empty spaces. The gate connection pattern 30, the contact connection pattern 40, and the conductive line 24 may be formed in the empty spaces. The etching of the upper insulating layer 22 may be performed to remove the first portion of the upper insulating layer 22 and to re-open the first space 72. The lower portion 31 of the gate connection pattern 30 may be formed in the first space 72. The etching of the upper insulating layer 22 may also be performed to remove the second portion of the upper insulating layer 22 and to re-open the second space 73. The lower portion 41 of the contact connection pattern 40 may be formed in the second space 73. The gate connection pattern 30, the contact connection pattern 40, and the conductive line 24 may be formed at the same time.

In a method of fabricating a semiconductor device according to an embodiment of the inventive concept, the bridge portion GE3 may be formed using the bridge sacrificial pattern 63 as an etch mask, the gate sacrificial pattern 71 may be formed by etching the bridge sacrificial pattern 63, and the gate connection pattern 30 may be formed in an empty space, which is formed by removing the gate sacrificial pattern 71. Thus, it may be possible to reduce a misalignment issue from occurring between the bridge portion GE3 and the gate connection pattern 30.

In a method of fabricating a semiconductor device, according to an embodiment of the inventive concept, the upper portion UAC of the active contact AC may be formed using the contact sacrificial pattern 65 as an etch mask, and the contact connection pattern 40 may be formed in an empty space, which is formed by removing the contact sacrificial pattern 65. Thus, it may be possible to reduce a misalignment issue from occurring between the upper portion UAC of the active contact AC and the contact connection pattern 40.

In a method of fabricating a semiconductor device, according to an embodiment of the inventive concept, the gate connection pattern 30, the contact connection pattern 40, and the conductive lines 24 may be formed at the same time. Thus, it may be possible to simplify a process of fabricating a semiconductor device.

FIG. 12 is an enlarged cross-sectional view illustrating a semiconductor device according to an embodiment of the inventive concept. The semiconductor device of FIG. 12 may be similar to the semiconductor device of FIGS. 1A to 1F, except for the features to be described below and to the extent that an element is not described in detail with respect to these figures, it may be understood that the element is at least similar to a corresponding element that has been described elsewhere within the present disclosure.

Referring to FIG. 12, a gate connection pattern 130 may include a lower portion 131 and an upper portion 132. The lower portion 131 of the gate connection pattern 130 may include a first side surface 131_S1 in contact with a side surface 123_S of a bridge insulating layer 123 and a second side surface 131_S2 in contact with the capping insulating layer 21. The second side surface 131_S2 of the lower portion 131 of the gate connection pattern 130 might not be parallel to a side surface GE3_S of the bridge portion GE3. The side surfaces 131_S1 and 131_S2 of the lower portion 131 of the gate connection pattern 130 may be coplanar with a side surface 132_S of the upper portion 132 of the gate connection pattern 130.

A width of the bridge insulating layer 123 in the first direction D1 may increase as a level is lowered. A width of the lower portion 131 of the gate connection pattern 130 in the first direction D1 may decrease as a level is lowered. A width of the upper portion 132 of the gate connection pattern 130 in the first direction D1 may decrease as a level is lowered.

In an embodiment, after the formation of the first space 72 (e.g., see FIG. 11A), the first space 72 may be enlarged. A width of the enlarged first space in the first direction D1 may decrease as a level is lowered. The upper insulating layer 22 may fill the enlarged first space. The upper insulating layer 22 may be etched to open the enlarged first space 72, and then, the gate connection pattern 130 may be formed.

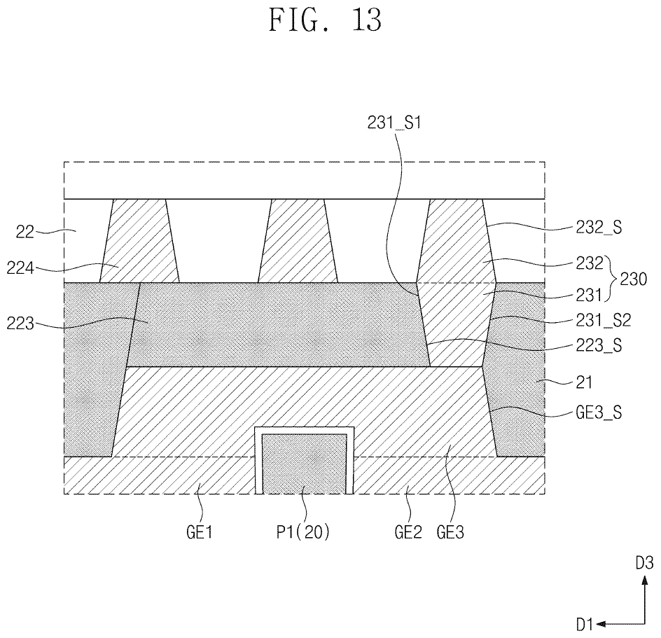

FIG. 13 is an enlarged cross-sectional view illustrating a semiconductor device according to an embodiment of the inventive concept. The semiconductor device of FIG. 13 may be similar to the semiconductor device of FIGS. 1A to 1F, except for the features to be described below and to the extent that an element is not described in detail with respect to these figures, it may be understood that the element is at least similar to a corresponding element that has been described elsewhere within the present disclosure.

Referring to FIG. 13, a gate connection pattern 230 may include a lower portion 231 and an upper portion 232. The lower portion 231 of the gate connection pattern 230 may include a first side surface 231_S1 in contact with a side surface 223_S of a bridge insulating layer 223 and a second side surface 231_S2 in contact with the capping insulating layer 21. The second side surface 231_S2 of the lower portion 231 of the gate connection pattern 230 might not be parallel to the side surface GE3_S of the bridge portion GE3. The side surfaces 231_S1 and 231_S2 of the lower portion 231 of the gate connection pattern 230 might not be parallel to a side surface 232_S of the upper portion 232 of the gate connection pattern 230.

A width of the lower portion 231 of the gate connection pattern 230 in the first direction D1 may decrease as a level is lowered. A width of the upper portion 232 of the gate connection pattern 230 in the first direction D1 may increase as a level is lowered. A width of a conductive line 224 in the first direction D1 may increase as a level is lowered.

In an embodiment, after the formation of the first space 72 (e.g., see FIG. 11A), the first space 72 may be enlarged. A preliminary conductive layer may fill the enlarged first space. The preliminary conductive layer may cover the bridge insulating layer 223 and the capping insulating layer 21. The preliminary conductive layer may be etched to form the conductive line 224 and the upper portion 232 of the gate connection pattern 230. Next, the upper insulating layer 22 may be formed.

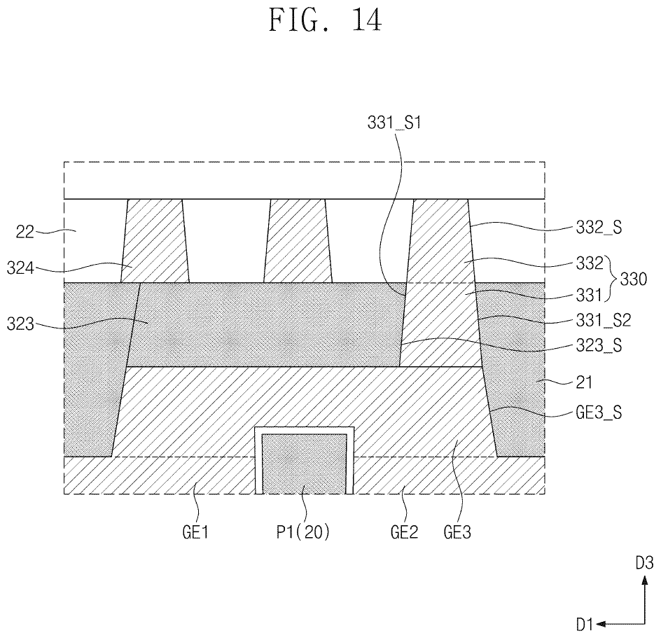

FIG. 14 is an enlarged cross-sectional view illustrating a semiconductor device according to an embodiment of the inventive concept. The semiconductor device of FIG. 14 may be similar to the semiconductor device of FIGS. 1A to 1F, except for the features to be described below and to the extent that an element is not described in detail with respect to these figures, it may be understood that the element is at least similar to a corresponding element that has been described elsewhere within the present disclosure.

Referring to FIG. 14, a gate connection pattern 330 may include a lower portion 331 and an upper portion 332. The lower portion 331 of the gate connection pattern 330 may include a first side surface 331_S1 in contact with a side surface 323_S of a bridge insulating layer 323 and a second side surface 331_S2 in contact with the capping insulating layer 21. The second side surface 331_S2 of the lower portion 331 of the gate connection pattern 330 may be coplanar with the side surface GE3_S of the bridge portion GE3. The second side surface 331_S2 of the lower portion 331 of the gate connection pattern 330 may be parallel to the side surface GE3_S of the bridge portion GE3. The side surfaces 331_S1 and 331_S2 of the lower portion 331 of the gate connection pattern 330 may be coplanar with a side surface 332_S of the upper portion 332 of the gate connection pattern 330.

A width of the lower portion 331 of the gate connection pattern 330 in the first direction D1 may increase as a level is lowered. A width of the upper portion 332 of the gate connection pattern 330 in the first direction D1 may increase as a level is lowered.

In an embodiment, after the formation of the first space 72 (e.g., see FIG. 11A), a preliminary conductive layer may fill the first space 72. The preliminary conductive layer may cover the bridge insulating layer 323 and the capping insulating layer 21. The preliminary conductive layer may be etched to form a conductive line 324 and the upper portion 332 of the gate connection pattern 330. Next, the upper insulating layer 22 may be formed.

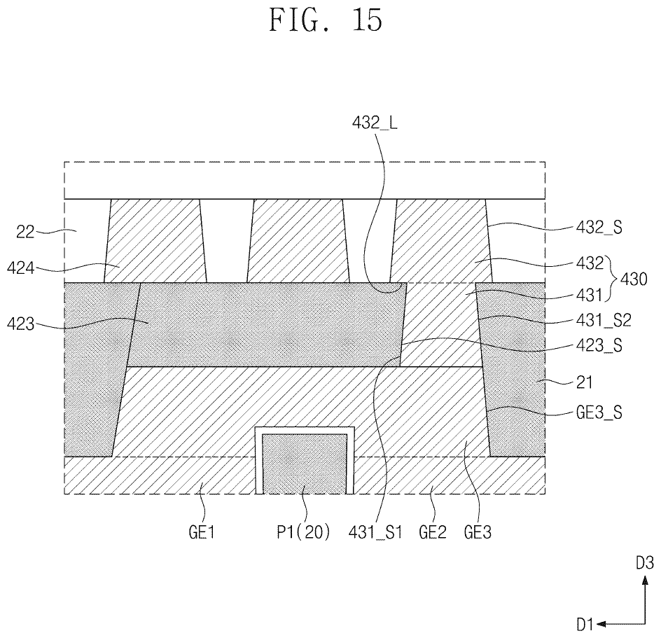

FIG. 15 is an enlarged cross-sectional view illustrating a semiconductor device according to an embodiment of the inventive concept. The semiconductor device of FIG. 15 may be similar to the semiconductor device of FIGS. 1A to 1F, except for the features to be described below and to the extent that an element is not described in detail with respect to these figures, it may be understood that the element is at least similar to a corresponding element that has been described elsewhere within the present disclosure.

Referring to FIG. 15, a gate connection pattern 430 may include a lower portion 431 and an upper portion 432. The lower portion 431 of the gate connection pattern 430 may include a first side surface 431_S1 in contact with a side surface 423_S of a bridge insulating layer 423 and a second side surface 431_S2 in contact with the capping insulating layer 21. The second side surface 431_S2 of the lower portion 431 of the gate connection pattern 430 may be coplanar with the side surface GE3_S of the bridge portion GE3. The second side surface 431_S2 of the lower portion 431 of the gate connection pattern 430 may be parallel to the side surface GE3_S of the bridge portion GE3.

The upper portion 432 of the gate connection pattern 430 may include a bottom surface 432_L connecting a side surface 432_S of the upper portion 432 of the gate connection pattern 430 and the side surfaces 431_S1 and 431_S2 of the lower portion 431 of the gate connection pattern 430. The bottom surface 432_L of the upper portion 432 of the gate connection pattern 430 may be in contact with the top surface of the capping insulating layer 21 and the top surface of the bridge insulating layer 423.

A width of the upper portion 432 of the gate connection pattern 430 in the first direction D1 may be larger than a width of the lower portion 431 of the gate connection pattern 430 in the first direction D1. A width of a conductive line 424 in the first direction D1 may be larger than a width of the lower portion 431 of the gate connection pattern 430 in the first direction D1.

In a semiconductor device, according to an embodiment of the inventive concept, a gate electrode may include a bridge portion, and it may be unnecessary to connect a contact and a conductive line to each of channel overlap portions. Thus, it may be possible to reduce the size and the fabrication cost of the semiconductor device.

While example embodiments of the inventive concept have been particularly shown and described, it will be understood by one of ordinary skill in the art that variations in form and detail may be made therein without departing from the spirit and scope of the present disclosure.

1. A semiconductor device, comprising:
a first source/drain structure and a second source/drain structure spaced apart from the first source/drain structure;
a first channel structure connected to the first source/drain structure;
a second channel structure connected to the second source/drain structure;
a separation insulating layer disposed between the first source/drain structure and the second source/drain structure and also disposed between the first channel structure and the second channel structure; and
a gate electrode overlapping the separation insulating layer, the first channel structure, and the second channel structure,
wherein the gate electrode comprises:
a first channel overlap portion overlapping the first channel structure;
a second channel overlap portion overlapping the second channel structure; and
a bridge portion disposed between the first channel overlap portion and the second channel overlap portion,
wherein a level of a top surface of the bridge portion is higher than a level of a top surface of the first channel overlap portion and a level of a top surface of the second channel overlap portion.

2. The semiconductor device of claim 1, wherein the first channel overlap portion and the second channel overlap portion are spaced apart from each other,
wherein the separation insulating layer is disposed between the first channel overlap portion and the second channel overlap portion, and
wherein the bridge portion overlaps the separation insulating layer.

3. The semiconductor device of claim 1, wherein the bridge portion comprises:
a first side surface connecting the top surface of the bridge portion to the top surface of the first channel overlap portion; and
a second side surface connecting the top surface of the bridge portion to the top surface of the second channel overlap portion,
wherein a distance between the first side surface of the bridge portion and the second side surface of the bridge portion increases as a level is lowered.

4. The semiconductor device of claim 1, wherein a level of a top surface of a portion of the separation insulating layer, which overlaps the bridge portion, is higher than a level of the top surface of the first channel overlap portion and a level of the top surface of the second channel overlap portion.

5. The semiconductor device of claim 4, wherein a level of the top surface of the portion of the separation insulating layer is lower than a level of the top surface of the bridge portion.

6. The semiconductor device of claim 1, wherein the first channel overlap portion and the second channel overlap portion are spaced apart from each other in a first direction,
wherein the semiconductor device further comprises a gate connection pattern in contact with the top surface of the bridge portion, and
wherein a width of the gate connection pattern in the first direction is smaller than a width of the bridge portion in the first direction.

7. The semiconductor device of claim 1, further comprising a bridge insulating layer in contact with the top surface of the bridge portion,
wherein a side surface of the bridge insulating layer is coplanar with a side surface of the bridge portion.

8. The semiconductor device of claim 7, further comprising a capping insulating layer in contact with the top surface of the first channel overlap portion, the side surface of the bridge portion, and the side surface of the bridge insulating layer,
wherein the capping insulating layer has an inclined side surface.

9. A semiconductor device, comprising:
a first source/drain structure and a second source/drain structure spaced apart from the first source/drain structure;
a first channel structure connected to the first source/drain structure;
a second channel structure connected to the second source/drain structure;
a separation insulating layer disposed between the first source/drain structure and the second source/drain structure and between the first channel structure and the second channel structure; and
a gate electrode overlapping the separation insulating layer, the first channel structure, and the second channel structure,
wherein the gate electrode comprises:
a first channel overlap portion overlapping the first channel structure;
a second channel overlap portion overlapping the second channel structure; and
a bridge portion connecting the first channel overlap portion to the second channel overlap portion,
wherein the bridge portion comprises:
a first portion connected to the first channel overlap portion;
a second portion connected to the second channel overlap portion; and
a third portion disposed between the first portion and the second portion,
wherein the third portion of the bridge portion is disposed at a level that is higher than the separation insulating layer, and
wherein the third portion of the bridge portion is overlapping the separation insulating layer.

10. The semiconductor device of claim 9, wherein a width of the first portion of the bridge portion increases as a level is lowered, and
wherein a width of the second portion of the bridge portion increases as a level is lowered.

11. The semiconductor device of claim 9, further comprising a gate cutting insulating layer in contact with a side surface of the first channel overlap portion,
wherein the bridge portion is disposed at a level that is higher than a top surface of the gate cutting insulating layer.

12. The semiconductor device of claim 11, wherein a top surface of the first channel overlap portion is coplanar with the top surface of the gate cutting insulating layer.

13. The semiconductor device of claim 11, wherein the separation insulating layer comprises a portion that overlaps the third portion of the bridge portion, and
wherein a level of a top surface of the portion of the separation insulating layer is higher than a level of the top surface of the gate cutting insulating layer.

14. The semiconductor device of claim 9, wherein the first channel overlap portion and the second channel overlap portion are spaced apart from each other in a first direction, and
wherein a width of the bridge portion in the first direction is smaller than a sum of widths of the first channel structure, the second channel structure, and the separation insulating layer in the first direction.

15. The semiconductor device of claim 9, wherein the first channel overlap portion and the second channel overlap portion are spaced apart from each other in a first direction,
wherein the semiconductor device further comprises a gate connection pattern, which is in contact with a top surface of the second portion of the bridge portion, and
wherein a width of the gate connection pattern in the first direction is smaller than a width of the second portion of the bridge portion in the first direction.

16. The semiconductor device of claim 15, wherein the gate connection pattern comprises a lower portion and an upper portion, and
wherein a side surface of the lower portion of the gate connection pattern is coplanar with a side surface of the second portion of the bridge portion.

17. The semiconductor device of claim 16, wherein the lower portion of the gate connection pattern has an increasing width as a level is lowered, and
wherein the upper portion of the gate connection pattern has a decreasing width as a level is lowered.

18. The semiconductor device of claim 15, further comprising a bridge insulating layer in contact with top surfaces of the first and third portions of the bridge portion,
wherein a side surface of the bridge insulating layer is coplanar with a side surface of the first portion of the bridge portion.

19. A semiconductor device, comprising:
a first source/drain structure and a second source/drain structure spaced apart from the first source/drain structure;
a first channel structure connected to the first source/drain structure;
a second channel structure connected to the second source/drain structure;
a first active contact disposed on the first source/drain structure;
a second active contact disposed on the second source/drain structure;
a separation insulating layer disposed between the first source/drain structure and the second source/drain structure, between the first channel structure and the second channel structure, and between the first active contact and the second active contact;
a gate electrode overlapping the separation insulating layer, the first channel structure, and the second channel structure;
a gate insulating layer disposed between the gate electrode and the separation insulating layer;
a capping insulating layer disposed on the first active contact, the second active contact, and the gate electrode; and
a gate connection pattern disposed on the gate electrode;
a bridge insulating layer in contact with the gate electrode, the gate connection pattern, and the capping insulating layer; and
a contact connection pattern disposed on the first active contact,
wherein the gate electrode comprises a bridge portion in contact with the bridge insulating layer and the gate connection pattern, and
wherein a width of the bridge portion increases as a level is lowered.

20. The semiconductor device of claim 19, wherein the first active contact comprises a lower portion in contact with the first source/drain structure and an upper portion in contact with the contact connection pattern, and
wherein a width of the upper portion of the first active contact increases as a level is lowered.

21-27. (canceled)
